(19) United States
(12) Patent Application Publication
(10) Pub. No.: US 2026/0096366 A1
(43) Pub. Date: Apr. 2, 2026

(54) PROCESSING METHOD, METHOD OF MANUFACTURING SEMICONDUCTOR DEVICE, PROCESSING APPARATUS, AND RECORDING MEDIUM

(71) Applicant: Kokusai Electric Corporation, Tokyo (JP)

(72) Inventors: Ryuji Yamamoto, Tokyo (JP); Takayuki Yamamoto, Toyama-shi (JP); Kaigo Tahara, Toyama-shi (JP); Hideki Horita, Toyama-shi (JP)

(73) Assignee: Kokusai Electric Corporation, Tokyo (JP)

(21) Appl. No.: 19/314,266

(22) Filed: Aug. 29, 2025

(30) Foreign Application Priority Data
Oct. 2, 2024 (JP) 2024-173029

(51) Int. Cl. H01L 21/311; C23C 16/02; C23C 16/34; C23C 16/56; H01J 37/32; H01L 21/02

(52) U.S. Cl. CPC H10P 50/283; C23C 16/0236; C23C 16/345; C23C 16/56; H01J 37/32449; H10P 14/69433; H01J 2237/332

(57) ABSTRACT

There is provided a technique that includes: (a) preparing a substrate including a nitrogen-containing film, which is formed to be thicker by a thickness T₂ than a target thickness T₁, and an oxide film on a surface of the substrate; and (b) etching the oxide film on the surface of the substrate using a substance X generated by supplying a fluorine-containing substance to the substrate and chemically reacting the nitrogen-containing film with the fluorine-containing substance.

### CROSS-REFERENCE TO RELATED APPLICATION

This application is based upon and claims the benefit of priority from Japanese Patent Application No. 2024-173029, filed on Oct. 2, 2024, the entire contents of which are incorporated herein by reference.

### TECHNICAL FIELD

The present disclosure relates to a processing method, a method of manufacturing a semiconductor device, a processing apparatus, and a recording medium.

### BACKGROUND

In the related art, as a process of manufacturing a semiconductor device, a process of etching an oxide film on the surface of a substrate may be often carried out.

### SUMMARY

Some embodiments of the present disclosure provide a technique capable of efficiently etching an oxide film on the surface of a substrate.

According to embodiments of the present disclosure, there is provided a technique that includes: (a) preparing a substrate including a nitrogen-containing film, which is formed to be thicker by a thickness T₂ than a target thickness T₁, and an oxide film on a surface of the substrate; and (b) etching the oxide film on the surface of the substrate using a substance X generated by supplying a fluorine-containing substance to the substrate and chemically reacting the nitrogen-containing film with the fluorine-containing substance.

### BRIEF DESCRIPTION OF DRAWINGS

The accompanying drawings, which are incorporated in and constitute a part of the specification, illustrate embodiments of the present disclosure.

FIG. 1 is a schematic configuration view of a vertical process furnace of a processing apparatus suitably used in embodiments of the present disclosure, in which a portion of the process furnace 202 is shown in a vertical cross section.

FIG. 2 is a schematic configuration view of the vertical process furnace of the processing apparatus suitably used in the embodiments of the present disclosure, in which a portion of the process furnace 202 is shown in a cross section taken along line A-A in FIG. 1.

FIG. 3 is a schematic configuration diagram of a controller 121 of the processing apparatus suitably used in the embodiments of the present disclosure, in which a control system of the controller 121 is shown in a block diagram.

FIG. 4A is a partially enlarged cross-sectional view showing a surface portion of a substrate according to embodiments of the present disclosure, the surface of which includes a stacked film of a first nitrogen (N)-containing film and a second nitrogen (N)-containing film, and an oxide film formed on a base.

FIG. 4B is a partially enlarged cross-sectional view showing a surface portion of the substrate according to the embodiments of the present disclosure after a fluorine (F)-containing substance is supplied from the state of FIG. 4A to chemically react the surface of the second N-containing film with the F-containing substance to generate a reaction product.

FIG. 4C is a partially enlarged cross-sectional view showing a surface portion of the substrate according to the embodiments of the present disclosure after the reaction product is decomposed to generate a substance X while the supply of the F-containing substance is continued from the state of FIG. 4B.

FIG. 4D is a partially enlarged cross-sectional view showing a surface portion of the substrate according to the embodiments of the present disclosure after a portion of the surface side of the oxide film is etched using the substance X while the supply of the F-containing substance is continued from the state of FIG. 4C.

FIG. 4E is a partially enlarged cross-sectional view showing a surface portion of the substrate according to the embodiments of the present disclosure after the second N-containing film and the oxide film are removed to expose the surfaces of the first N-containing film and the base, respectively, while the supply of the F-containing substance is continued from the state of FIG. 4D.

FIG. 4F is a partially enlarged cross-sectional view showing a surface portion of the substrate according to the embodiments of the present disclosure after a film is formed on the surface of each of the first N-containing film and the base from the state of FIG. 4E.

FIG. 5A is a partially enlarged cross-sectional view showing a surface portion of a substrate according to a modification of the embodiments of the present disclosure, the surface of which includes a first N-containing film and an oxide film formed on a base.

FIG. 5B is a partially enlarged cross-sectional view showing a surface portion of the substrate according to the modification of the embodiments of the present disclosure after an inhibitor is adsorbed on the surface of the oxide film from the state of FIG. 5A.

FIG. 5C is a partially enlarged cross-sectional view showing a surface portion of the substrate according to the modification of the embodiments of the present disclosure after a second N-containing film is formed on the first N-containing film from the state of FIG. 5B.

FIG. 5D is a partially enlarged cross-sectional view showing a surface portion of the substrate according to the modification of the embodiments of the present disclosure after an inhibitor remaining on the surface of the oxide film is removed from the state of FIG. 5C.

FIG. 6A is a partially enlarged cross-sectional view showing a surface portion of a substrate according to a modification of the embodiments of the present disclosure, the surface of which includes an oxide film formed on a base.

FIG. 6B is a partially enlarged cross-sectional view showing a surface portion of the substrate according to the modification of the embodiments of the present disclosure after an inhibitor is adsorbed on the surface of the oxide film from the state of FIG. 6A.

FIG. 6C is a partially enlarged cross-sectional view showing a surface portion of the substrate according to the modification of the embodiments of the present disclosure after a stacked film of a first N-containing film and a second N-containing film is formed on the surface from the state of FIG. 6B.

FIG. 6D is a partially enlarged cross-sectional view showing a surface portion of the substrate according to the modification of the embodiments of the present disclosure after an inhibitor remaining on the surface of the oxide film is removed from the state of FIG. 6C.

FIG. 7A is a partially enlarged cross-sectional view showing a surface portion of a substrate according to other embodiments of the present disclosure, the surface of which includes a first base and a second base on the surface thereof, an oxide film formed on the surface of the first base, and a N-containing film formed on the surface of the second base.

FIG. 7B is a partially enlarged cross-sectional view showing a surface portion of the substrate according to the other embodiments of the present disclosure after an F-containing substance is supplied from the state of FIG. 7A to chemically react the surface of the N-containing film with the F-containing substance to generate a reaction product.

FIG. 7C is a partially enlarged cross-sectional view showing a surface portion of the substrate according to the other embodiments of the present disclosure after the reaction product is decomposed to generate a substance X while the supply of the F-containing substance is continued from the state of FIG. 7B.

FIG. 7D is a partially enlarged cross-sectional view showing a surface portion of the substrate according to the other embodiments of the present disclosure after a portion of the surface side of the oxide film is etched using the substance X while the supply of the F-containing substance is continued from the state of FIG. 7C.

FIG. 7E is a partially enlarged cross-sectional view showing a surface portion of the substrate according to the other embodiments of the present disclosure after the N-containing film and the oxide film are removed to expose the surfaces of the second base and the first base, respectively, while the supply of the F-containing substance is continued from the state of FIG. 7D.

FIG. 7F is a partially enlarged cross-sectional view showing a surface portion of the substrate according to the other embodiments of the present disclosure after a film is formed on the surface of each of the second base and the first base from the state of FIG. 7E.

FIG. 8A is a partially enlarged cross-sectional view showing a surface portion of a substrate according to other embodiments of the present disclosure, the surface of which includes a first base and a second base and an oxide film formed on the surface of the first base.

FIG. 8B is a partially enlarged cross-sectional view showing a surface portion of the substrate according to the other embodiments of the present disclosure after an inhibitor is adsorbed on the surface of the oxide film from the state of FIG. 8A.

FIG. 8C is a partially enlarged cross-sectional view showing a surface portion of the substrate according to the other embodiments of the present disclosure after a N-containing film is formed on the surface of the second base from the state of FIG. 8B.

FIG. 8D is a partially enlarged cross-sectional view showing a surface portion of the substrate according to the other embodiments of the present disclosure after an inhibitor remaining on the surface of the oxide film is removed from the state of FIG. 8C.

FIG. 9 is a schematic configuration view of a processing apparatus suitably used in other embodiments of the present disclosure.

FIG. 10 is a schematic configuration view of a processing apparatus suitably used in other embodiments of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### Embodiments of the Present Disclosure

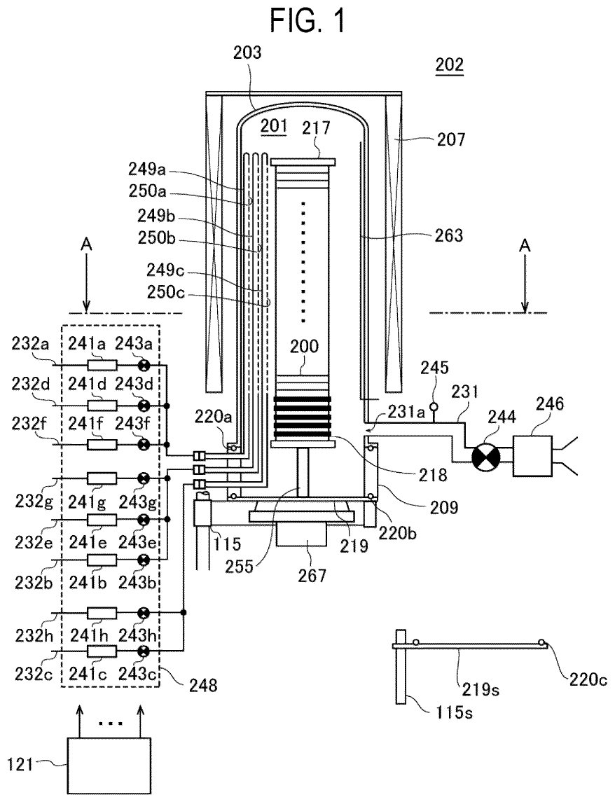

Embodiments of the present disclosure will now be described mainly with reference to FIGS. 1 to 3 and 4A to 4F. The drawings used in the following description are all schematic, and the dimensional relationship, ratios, and the like of various elements shown in the drawings do not always match the actual ones. Further, the dimensional relationship, ratios, and the like of various elements between plural figures do not always match each other.

### (1) Configuration of Processing Apparatus

As shown in FIG. 1, a process furnace 202 of a processing apparatus includes a heater 207 as a temperature adjustor (a heating part). The heater 207 has a cylindrical shape and is supported by a support plate so as to be vertically installed. The heater 207 functions as an activation mechanism (an excitation part) that thermally activates (excites) a gas.

A reaction tube 203 is disposed inside the heater 207 to be concentric with the heater 207. The reaction tube 203 is made of, for example, a heat resistant material such as quartz (SiO₂) or silicon carbide (SiC), and has a cylindrical shape with its upper end closed and its lower end opened. A manifold 209 is disposed to be concentric with the reaction tube 203 under the reaction tube 203. The manifold 209 is made of, for example, a metal material such as stainless steel (SUS), and has a cylindrical shape with both of its upper and lower ends opened. The upper end portion of the manifold 209 engages with the lower end portion of the reaction tube 203 so as to support the reaction tube 203. An O-ring 220a serving as a seal member is provided between the manifold 209 and the reaction tube 203. Similar to the heater 207, the reaction tube 203 is vertically installed. A process container (reaction container) mainly includes the reaction tube 203 and the manifold 209. A process chamber 201 is formed in a hollow cylindrical portion of the process container. The process chamber 201 is configured to accommodate a plurality of wafers 200 as substrates. Processing on the wafers 200 is performed in the process chamber 201.

Nozzles 249a to 249c as first to third supply parts are provided in the process chamber 201 so as to penetrate through a sidewall of the manifold 209. The nozzles 249a to 249c are also referred to as first to third nozzles, respectively. The nozzles 249a to 249c are made of, for example, a heat resistant material such as quartz or SiC. Gas supply pipes 232a to 232c are connected to the nozzles 249a to 249c, respectively. The nozzles 249a to 249c are different nozzles, and each of the nozzles 249a and 249c is provided adjacent to the nozzle 249b.

Mass flow controllers (MFCs) 241a to 241c, which are flow rate controllers (flow rate control parts), and valves 243a to 243c, which are opening/closing valves, are provided in the gas supply pipes 232a to 232c, respectively, sequentially from the upstream side of a gas flow. Each of gas supply pipes 232d and 232f is connected to the gas supply pipe 232a at the downstream side of the valves 243a. Each of gas supply pipes 232e and 232g is connected to the gas supply pipe 232b at the downstream side of the valves 243b. A gas supply pipe 232h is connected to the gas supply pipe 232c at the downstream side of the valves 243c. MFCs 241d to 241h and valves 243d to 243h are provided in the gas supply pipes 232d to 232h, respectively, sequentially from the upstream side of a gas flow. The gas supply pipes 232a to 232h are made of, for example, a metal material such as SUS.

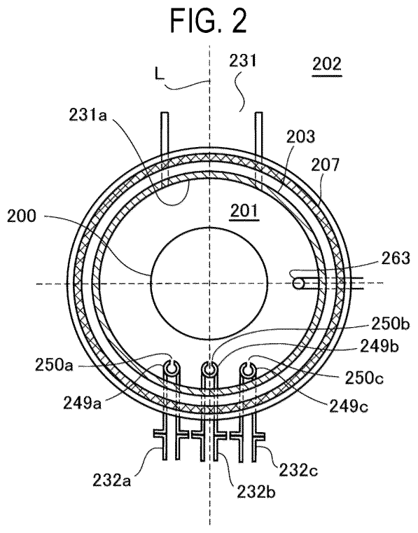

As shown in FIG. 2, each of the nozzles 249a to 249c is provided in an annular space (in a plane view) between an inner wall of the reaction tube 203 and the wafers 200 so as to extend upward from a lower portion of the inner wall of the reaction tube 203 to an upper portion thereof, that is, along an arrangement direction of the wafers 200. Specifically, each of the nozzles 249a to 249c is provided in a region horizontally surrounding a wafer arrangement region in which the wafers 200 are arranged at a lateral side of the wafer arrangement region, along the wafer arrangement region. In a plane view, the nozzle 249b is disposed so as to face an exhaust port 231a to be described later on a straight line with the centers of the wafers 200 in the process chamber 201, which are interposed therebetween. The nozzles 249a and 249c are arranged so as to sandwich a straight line L passing through the nozzle 249b and the center of the exhaust port 231a from both sides along the inner wall of the reaction tube 203 (the outer peripheral portion of the wafers 200). The straight line L is also a straight line passing through the nozzle 249b and the centers of the wafers 200. That is, it can be said that the nozzle 249c is provided on the side opposite to the nozzle 249a with the straight line L interposed therebetween. The nozzles 249a and 249c are arranged in line symmetry with the straight line L as the axis of symmetry. Gas supply holes 250a to 250c for supplying a gas are formed on the side surfaces of the nozzles 249a to 249c, respectively. Each of the gas supply holes 250a to 250c is opened so as to oppose (face) the exhaust port 231a in a plane view, which enables a gas to be supplied toward the wafers 200. A plurality of gas supply holes 250a to 250c are formed from the lower portion of the reaction tube 203 to the upper portion thereof.

A fluorine (F)-containing substance is supplied from the gas supply pipe 232a into the process chamber 201 via the MFC 241a, the valve 243a, and the nozzle 249a.

A first precursor and a second precursor are supplied from the gas supply pipe 232b into the process chamber 201 via the MFC 241b, the valve 243b, and the nozzle 249b. The first precursor is used as one of first film-forming agents. The second precursor is used as one of second film-forming agents.

A dopant agent is supplied from the gas supply pipe 232c into the process chamber 201 via the MFC 241c, the valve 243c, and the nozzle 249c. The dopant agent is used as one of the first film-forming agents.

A modifying agent is supplied from the gas supply pipe 232d into the process chamber 201 via the MFC 241d, the valve 243d, the gas supply pipe 232a, and the nozzle 249a.

A reactant and a removing agent are supplied from the gas supply pipe 232e into the process chamber 201 via the MFC 241e, the valve 243e, the gas supply pipe 232b, and the nozzle 249b. The reactant is used as one of the second film-forming agents.

An inert gas is supplied from the gas supply pipes 232f to 232h into the process chamber 201 via the MFCs 241f to 241h, the valves 243f to 243h, the gas supply pipes 232a to 232c, and the nozzles 249a to 249c, respectively. The inert gas acts as a purge gas, a carrier gas, a dilution gas, or the like.

A F-containing substance supply system mainly includes the gas supply pipe 232a, the MFC 241a, and the valve 243a. A first precursor supply system and a second precursor supply system mainly include the gas supply pipe 232b, the MFC 241b, and the valve 243b. A dopant agent supply system mainly includes the gas supply pipe 232c, the MFC 241c, and the valve 243c. A modifying agent supply system mainly includes the gas supply pipe 232d, the MFC 241d, and the valve 243d. A reactant supply system and a removing agent supply system mainly include the gas supply pipe 232e, the MFC 241e, and the valve 243e. An inert gas supply system mainly includes the gas supply pipes 232f to 232h, the MFCs 241f to 241h, and the valves 243f to 243h. Each or both of the first precursor supply system and the dopant agent supply system are also referred to as a first film-forming agent supply system. Each or both of the second precursor supply system and the reactant supply system are also referred to as a second film-forming agent supply system.

One or all of the above-described various supply systems may be configured as an integrated-type supply system 248 in which the valves 243a to 243h, the MFCs 241a to 241h, and so on are integrated. The integrated-type supply system 248 is connected to each of the gas supply pipes 232a to 232h. In addition, the integrated-type supply system 248 is configured such that operations of supplying various substances (various gases) into the gas supply pipes 232a to 232h (that is, the opening/closing operation of the valves 243a to 243h, the flow rate adjustment operation by the MFCs 241a to 241h, and the like) are controlled by a controller 121 which will be described later. The integrated-type supply system 248 is configured as an integral type or detachable-type integrated unit, and may be attached to and detached from the gas supply pipes 232a to 232h and the like on an integrated unit basis, so that the maintenance, replacement, extension, etc. of the integrated-type supply system 248 can be performed on an integrated unit basis.

The exhaust port 231a for exhausting an internal atmosphere of the process chamber 201 is provided below the sidewall of the reaction tube 203. As shown in FIG. 2, in a plane view, the exhaust port 231a is provided at a position opposing (facing) the nozzles 249a to 249c (the gas supply holes 250a to 250c) with the wafers 200 interposed therebetween. The exhaust port 231a may be provided from a lower portion of the sidewall of the reaction tube 203 to an upper portion thereof, that is, along the wafer arrangement region. An exhaust pipe 231 is connected to the exhaust port 231a. A vacuum exhaust device, for example, a vacuum pump 246, is connected to the exhaust pipe 231 via a pressure sensor 245, which is a pressure detector (pressure detection part) for detecting the internal pressure of the process chamber 201, and an auto pressure controller (APC) valve 244, which is a pressure regulator (pressure adjustment part). The APC valve 244 is configured to perform or stop a vacuum exhausting operation in the process chamber 201 by opening/closing the valve while the vacuum pump 246 is actuated, and is also configured to adjust the internal pressure of the process chamber 201 by adjusting an opening degree of the valve based on pressure information detected by the pressure sensor 245 while the vacuum pump 246 is actuated. An exhaust system mainly includes the exhaust pipe 231, the APC valve 244, and the pressure sensor 245. The exhaust system may include the vacuum pump 246.

A seal cap 219, which serves as a furnace opening cover configured to hermetically seal a lower end opening of the manifold 209, is provided under the manifold 209. The seal cap 219 is made of, for example, a metal material such as SUS, and is formed in a disc shape. An O-ring 220b, which is a seal member making contact with the lower end of the manifold 209, is provided on an upper surface of the seal cap 219. A rotation mechanism 267 configured to rotate a boat 217, which will be described later, is installed under the seal cap 219. A rotary shaft 255 of the rotation mechanism 267 is connected to the boat 217 through the seal cap 219. The rotation mechanism 267 is configured to rotate the wafers 200 by rotating the boat 217. The seal cap 219 is configured to be vertically moved up and down by a boat elevator 115 which is an elevating mechanism installed outside the reaction tube 203. The boat elevator 115 is configured as a transfer device (transfer mechanism) which loads/unloads (transfers) the wafers 200 into/out of the process chamber 201 by moving the seal cap 219 up and down, and functions as a device (preparation device) for preparing a substrate in the process container. When a substrate to be processed is prepared in the process chamber 201, that is, when a predetermined film is formed on the surface of the substrate in the process chamber 201 to prepare the substrate to be processed, as in a modification which will be described later, each part (such as the modifying agent supply system, the second film-forming agent supply system, the removing agent supply system, etc.) of the processing apparatus used to form the film and the boat elevator 115 function as the preparation device.

A shutter 219s, which serves as a furnace opening cover configured to hermetically seal a lower end opening of the manifold 209 in a state where the seal cap 219 is lowered and the boat 217 is unloaded from the process chamber 201, is provided under the manifold 209. The shutter 219s is made of, for example, a metal material such as SUS, and is formed in a disc shape. An O-ring 220c, which is a seal member making contact with the lower end of the manifold 209, is provided on an upper surface of the shutter 219s. The opening/closing operation (such as elevation operation, rotation operation, or the like) of the shutter 219s is controlled by a shutter opening/closing mechanism 115s.

The boat 217 serving as a substrate support is configured to support a plurality of wafers 200, for example, 25 to 200 wafers, in such a state that the wafers 200 are arranged in a horizontal posture and in multiple stages along a vertical direction with the centers of the wafers 200 aligned with one another. That is, the boat 217 is configured to arrange the wafers 200 to be spaced apart from each other. The boat 217 is made of, for example, a heat resistant material such as quartz or SiC. Heat insulating plates 218 made of, for example, a heat resistant material such as quartz or SiC are installed below the boat 217 in multiple stages. The boat 217 may also be considered a part of the above-mentioned preparation device.

A temperature sensor 263 serving as a temperature detector is installed in the reaction tube 203. Based on temperature information detected by the temperature sensor 263, a state of supplying electric power to the heater 207 is adjusted such that an interior of the process chamber 201 has a desired temperature distribution. The temperature sensor 263 is provided along the inner wall of the reaction tube 203.

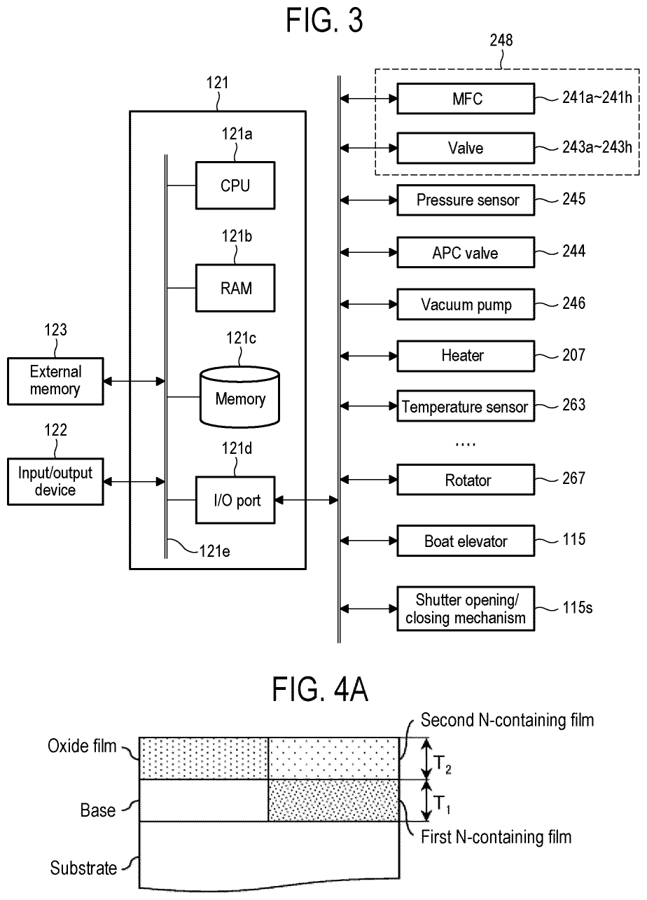

As shown in FIG. 3, a controller 121, which is a control part (control means), is configured as a computer including a central processing unit (CPU) 121a, a random access memory (RAM) 121b, a memory 121c, and an I/O port 121d. The RAM 121b, the memory 121c, and the I/O port 121d are configured to be capable of exchanging data with the CPU 121a via an internal bus 121e. An input/output device 122 formed of, e.g., a touch panel or the like, is connected to the controller 121. Further, an external memory 123 may be connected to the controller 121. Here, the processing apparatus may be configured to include one control part, or may be configured to include a plurality of control parts. That is, control for performing a processing sequence to be described later may be performed using one control part, or may be performed using a plurality of control parts. Further, the plurality of control parts may be configured as a control system in which the plurality of control parts are connected to each other via a wired or wireless communication network, and the entire control system may perform control for performing the processing sequence to be described later. When the term “control part” is used in the present disclosure, it may include not only one control part but also a plurality of control parts or a control system configured by a plurality of control parts.

The memory 121c is configured by, for example, a flash memory, a hard disk drive (HDD), a solid state drive (SSD), or the like. A control program for controlling operations of a processing apparatus, a process recipe in which sequences and conditions of substrate processing to be described later are written, etc. are readably recorded and stored in the memory 121c. The process recipe functions as a program for causing, by the controller 121, the processing apparatus to execute each sequence in the substrate processing, which will be described later, to obtain an expected result. Hereinafter, the process recipe and the control program may be generally and simply referred to as a “program (program product)”. Furthermore, the process recipe may be simply referred to as a “recipe”. When the term “program” is used herein, it may indicate a case of including the recipe only, a case of including the control program only, or a case of including both the recipe and the control program. The RAM 121b is configured as a memory area (work area) in which programs or data read by the CPU 121a are temporarily stored.

The I/O port 121d is connected to the MFCs 241a to 241h, the valves 243a to 243h, the pressure sensor 245, the APC valve 244, the vacuum pump 246, the temperature sensor 263, the heater 207, the rotation mechanism 267, the boat elevator 115, the shutter opening/closing mechanism 115s, and so on.

The CPU 121a is configured to read and execute the control program from the memory 121c. The CPU 121a is also configured to read the recipe from the memory 121c according to an input of an operation command from the input/output device 122. The CPU 121a is configured to control the flow rate adjusting operation of various kinds of substances (gases) by the MFCs 241a to 241h, the opening/closing operation of the valves 243a to 243h, the opening/closing operation of the APC valve 244, the pressure adjusting operation performed by the APC valve 244 based on the pressure sensor 245, the actuating and stopping operation of the vacuum pump 246, the temperature adjusting operation performed by the heater 207 based on the temperature sensor 263, the operation of rotating the boat 217 with the rotation mechanism 267 and adjusting the rotation speed of the boat 217, the operation of moving the boat 217 up and down by the boat elevator 115, the opening/closing operation of the shutter 219s by the shutter opening/closing mechanism 115s, and so on, according to contents of the read recipe.

The controller 121 may be configured by installing, on the computer, the aforementioned program recorded and stored in the external memory 123. Examples of the external memory 123 may include a magnetic disk such as a HDD, an optical disc such as a CD, a semiconductor memory such as a USB memory or a SSD, and the like. The memory 121c or the external memory 123 is configured as a non-transitory computer-readable recording medium. Hereinafter, the memory 121c and the external memory 123 may be generally and simply referred to as a “recording medium”. When the term “recording medium” is used herein, it may indicate a case of including the memory 121c only, a case of including the external memory 123 only, or a case of including both the memory 121c and the external memory 123. Furthermore, the program may be provided to the computer using communication means such as the Internet or a dedicated line, instead of using the external memory 123.

### (2) Processing Process

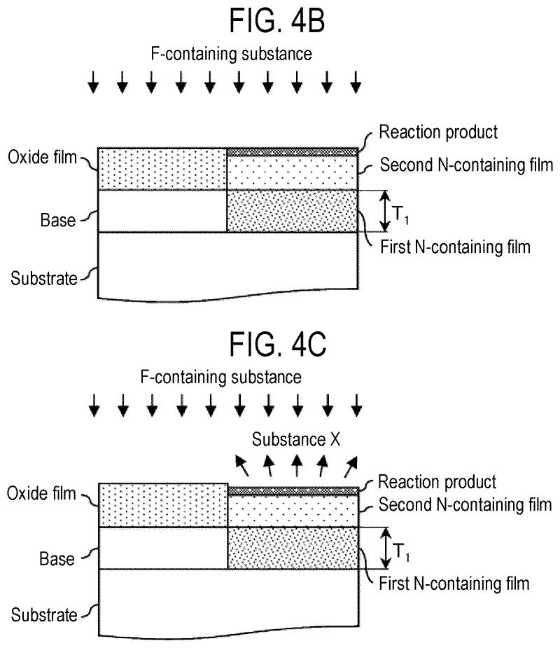

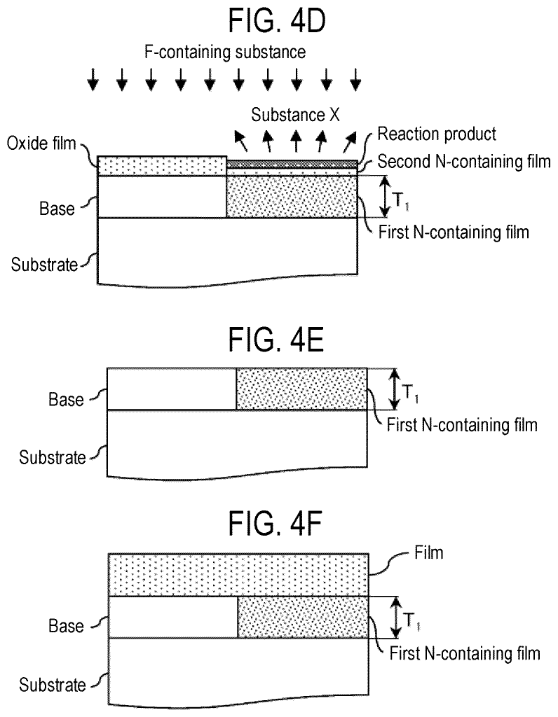

As a process (method) of manufacturing a semiconductor device using the above-described processing apparatus, an example of a method of processing a substrate, that is, a processing sequence that successively performs a processing sequence for etching the surface of a wafer 200 as a substrate and a processing sequence for growing a film on the wafer 200 after etching, will be described mainly with reference to FIGS. 4A to 4F. In the following description, the operations of the respective parts constituting the processing apparatus are controlled by the controller 121. The processing apparatus is also referred to as a substrate processing apparatus. The processing method is also referred to as a method of processing a substrate.

A processing sequence in the present embodiments includes:
(a) step A of preparing a wafer 200 including a nitrogen (N)-containing film, which is formed to be thicker by a thickness T₂ than the originally required thickness (i.e., target thickness) T₁, and an oxide film on the surface of the wafer 200; and
(b) step B of etching the oxide film on the surface of the wafer 200 using a substance X generated by supplying a F-containing substance to the wafer 200 and chemically reacting the N-containing film with the F-containing substance.

In the following example, a case of, after performing step B, further performing (c) step C of forming a film on the surface of the wafer 200 with the etched oxide film by supplying a first film-forming agent to the wafer 200 will be described.

When the term “wafer” is used in the present disclosure, it may refer to “a wafer itself” or “a wafer and a stacked body of certain layers or films formed on a surface of the wafer”. When the phrase “a surface of a wafer” is used in the present disclosure, it may refer to “a surface of a wafer itself” or “a surface of a certain layer formed on a wafer”. When the expression “a certain layer is formed on a surface of a wafer” is used in the present disclosure, it may mean that “a certain layer is formed directly on a surface of a wafer itself” or that “a certain layer is formed on a layer formed on a wafer”. When the term “substrate” is used in the present disclosure, it may be synonymous with the term “wafer”.

The terms “agent” and “substance” used in the present disclosure include at least one of a gaseous substance and a liquefied substance. The liquefied substance includes a misty substance. That is, each of the F-containing substance, the modifying agent, the removing agent, the first film-forming agent (the first precursor and the dopant agent), and the second film-forming agent (the second precursor and the reactant) may include a gaseous substance, a liquefied substance such as a misty substance, or both of them.

### Step A

First, the boat 217 is charged with a plurality of wafers 200 (wafer charging).

As described above, the N-containing film formed to be thicker by a thickness T₂ than the originally required thickness T₁ and an oxide film are formed in advance on the surface of the wafer 200. As shown in FIG. 4A, the N-containing film on the surface of the wafer 200 includes a stacked film of a first N-containing film having a thickness T₁ and a second N-containing film having a thickness T₂.

As described later, in step B, the oxide film is removed by etching, at which time a portion of the N-containing film having the thickness T₂ on the upper layer side is removed, and a portion of the N-containing film having the thickness T₁ on the lower layer side is left. The first N-containing film corresponds to the portion of the N-containing film having the thickness T₁ on the lower layer side, and is a necessary N-containing film, that is, a film that needs to remain on the wafer 200 without reducing its thickness from T₁ in step B. The second N-containing film corresponds to a portion of the N-containing film having the thickness T₂ on the upper layer side, and is an excess (unnecessary) portion of the N-containing film, that is, a film that needs to be removed from the wafer 200 in step B. The thickness T₂ is preset so as to be a thickness that allows the N-containing film to be removed in step B.

In the present disclosure, the portion of the N-containing film having the thickness T₁ on the lower layer side, which is a necessary film among the N-containing film, i.e., the first N-containing film having the thickness T₁, is also simply referred to as a first N-containing film. The portion of the N-containing film having the thickness T₂ on the upper layer side, which is an excess film among the N-containing film, i.e., the second N-containing film having the thickness T₂, is also simply referred to as a second N-containing film.

The first and second N-containing films may each include a film containing silicon (Si) as a semiconductor element, for example, a Si- and N-containing film such as a silicon nitride film (SiN film), a silicon carbonitride film (SiCN film), a silicon oxynitride film (SiON film), a silicon oxycarbonitride film (SiOCN film), a silicon borocarbonitride film (SiBCN film), or a silicon boronitride film (SiBN film). In addition, the first and second N-containing films may each include a metal element- and N-containing film, such as a titanium nitride film (TiN film), a tungsten nitride film (WN film), or an aluminum nitride film (AlN film). Note that the materials, properties, compositions, and constituent elements of these films may be the same or different. For example, the first N-containing film may be a SiN film, and the second N-containing film may be a SiN film. For example, the first N-containing film may be a SiCN film, and the second N-containing film may be a SiN film.

It is preferable to prepare the first and second N-containing films so that the etching resistance of the first N-containing film by the F-containing substance is higher than the etching resistance of the second N-containing film by the F-containing substance. It is also preferable to prepare the first and second N-containing films so that the etching resistance of the first N-containing film by the F-containing substance at least in a portion in contact with the second N-containing film is higher than the etching resistance of the second N-containing film by the F-containing substance.

The oxide film may include a silicon oxide film (SiO film). The oxide film may include at least one of a non-stoichiometric silicon oxide film (SiOₓ film, x is a real number less than 2) and a stoichiometric silicon oxide film (SiO₂ film). The oxide film may include at least one of a native oxide film and a chemical oxide film. The SiOₓ film and the SiO₂ film are collectively referred to as a SiO film below.

The base of the oxide film may include at least one of the following: a semiconductor element-containing substrate such as single crystal Si; a semiconductor element-containing film such as a silicon film (Si film), a germanium film (Ge film), or a silicon germanium film (SiGe film); a semiconductor element- and N-containing film such as a SiN film, a SiCN film, a SiON film, a SiOCN film, a SiBCN film, or a SiBN film; a metal element- and N-containing film such as a TiN film, a WN film, or an AlN film; a semiconductor element- and O-containing film such as a SiO film or a silicon oxycarbide film (SiOC film); a metal element- and O-containing film such as a titanium oxide film (TiO film), a hafnium oxide film (HfO film), a zirconium oxide film (ZrO film), or an aluminum oxide film (AlO film); and a metal element-containing film such as a tungsten film (W film), a molybdenum film (Mo film), or a ruthenium film (Ru film).

After the wafer charging is completed, the shutter 219s is moved by the shutter opening/closing mechanism 115s to open the lower end opening of the manifold 209 (shutter open). Then, as shown in FIG. 1, the boat 217 supporting the wafers 200 is lifted up by the boat elevator 115 to be loaded into the process chamber 201 (boat loading). In this state, the seal cap 219 seals the lower end of the manifold 209 via the O-ring 220b.

When the boat loading is completed, the substrate to be processed, that is, the wafer 200 including the N-containing film formed with the thickness T₂ thicker than the originally required thickness T₁ and the oxide film on the surface of the wafer 200 is prepared (placed) in the process chamber 201.

### (Pressure Adjustment and Temperature Adjustment)

After the boat loading is completed, the interior of the process chamber 201, that is, a space where the wafers 200 are placed, is vacuum-exhausted (decompression-exhausted) by the vacuum pump 246 to reach a desired pressure (degree of vacuum). At this time, the internal pressure of the process chamber 201 is measured by the pressure sensor 245, and the APC valve 244 is feedback-controlled based on the measured pressure information. Further, the wafers 200 in the process chamber 201 are heated by the heater 207 so as to have a desired processing temperature. At this time, the state of supplying electric power to the heater 207 is feedback-controlled based on the temperature information detected by the temperature sensor 263 so that the interior of the process chamber 201 has a desired temperature distribution. Further, the rotation of the wafers 200 by the rotation mechanism 267 is started. The exhaust of the interior of the process chamber 201 and the heating and rotation of the wafers 200 are continuously performed at least until the processing on the wafers 200 is completed.

### Step B

After that, a F-containing substance is supplied to the wafer 200 in the process chamber 201.

Specifically, the valve 243a is opened to allow the F-containing substance to flow into the gas supply pipe 232a. The flow rate of the F-containing substance is adjusted by the MFC 241a, and the F-containing substance is supplied into the process chamber 201 via the nozzle 249a and is exhausted through the exhaust port 231a. In this operation, the F-containing substance is supplied to the wafer 200 from the side of the wafer 200, so that the wafer 200 is exposed to the F-containing substance (F-containing substance supply, exposure). At this time, the valves 243f to 243h may be opened to allow an inert gas to be supplied into the process chamber 201 via the nozzles 249a to 249c, respectively.

By supplying the F-containing substance to the wafer 200 under the process conditions to be described later, it is possible to generate a substance X by chemically reacting a portion of the N-containing film with the thickness T₂, i.e., the second N-containing film, with the F-containing substance. The substance X is generated in the process of etching the second N-containing film by the F-containing substance. More specifically, the substance X is generated by decomposition of a reaction product generated in the process of etching the second N-containing film by the F-containing substance. The substance X contains nitrogen (N) and hydrogen (H). By generating the substance X in the process chamber 201 into which the F-containing substance is supplied, it is possible to efficiently etch the oxide film on the surface of the wafer 200 using the substance X.

For example, if the oxide film on the surface of the wafer 200 includes a silicon oxide film (SiO₂), the second N-containing film on the surface of the wafer 200 includes a silicon nitride film (Si₃N₄), and the F-containing substance supplied into the process chamber 201 includes hydrogen fluoride (HF), the reaction shown in the following formula can proceed under the conditions to be described later.

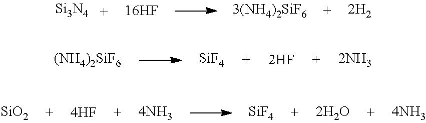

That is, on the surface of the wafer 200, as shown in FIG. 4B, it is possible to generate a solid reaction product such as ammonium silicofluoride, i.e., ammonium hexafluorosilicate ((NH₄)₂SiF₆) by chemically reacting the second N-containing film (Si₃N₄) with the F-containing substance (HF). In addition, on the surface of the wafer 200, as shown in FIG. 4C, it is possible to generate hydrogen nitride such as ammonia (NH₃) as the substance X by decomposing (thermally decomposing, etc.) this solid reaction product. By generating the substance X containing N and H, such as NH₃, under a situation where the F-containing substance (HF) exists, it is possible to promote the etching reaction of the oxide film (SiO₂) present on the surface of the wafer 200, as shown in FIG. 4D. In this step, it is possible to gradually thin the second N-containing film and the oxide film by etching these films in parallel by the supply of the F-containing substance to the wafer 200. Then, by continuing the supply of the F-containing substance to the wafer 200, it is possible to remove the second N-containing film and the oxide film, thereby exposing the surfaces of the first N-containing film and the base, as shown in FIG. 4E. That is, it is possible to remove the part of the N-containing film with the thickness T₂ while leaving the part thereof with the thickness T₁. In addition, in the process of removing the oxide film by the F-containing substance and the substance X, a solid reaction product such as (NH₄)₂SiF₆ may be generated again, but in this reaction system, once the solid reaction product is generated, it is immediately decomposed, and the above-mentioned reaction occurs in a chain. That is, in this reaction system, the reaction, the generation of solid reaction product, the decomposition of the solid reaction product, and the etching occur repeatedly in a chain, so it is possible to suppress the solid reaction product from remaining as a solid on the outermost surface of the oxide film to be etched.

According to the present disclosure, as described above, it is possible to start the etching reaction without triggering the reaction between the F-containing substance (HF) and water (H₂O). That is, according to the present disclosure, it is possible to start the etching reaction to etch the oxide film on the surface of the wafer 200 without having H₂O present in the process chamber 201 at the start of step B.

After the second N-containing film and the oxide film are removed, the valve 243a is closed to stop the supply of the F-containing substance into the process chamber 201. Then, the interior of the process chamber 201 is vacuum-exhausted to remove a gaseous substance and the like remaining in the process chamber 201 from the process chamber 201. At this time, the valves 243f to 243h are opened to allow an inert gas to be supplied into the process chamber 201 via the nozzles 249a to 249c, respectively. The inert gas supplied from the nozzles 249a to 249c acts as a purge gas, whereby the interior of the process chamber 201 is purged (purging).

The process conditions for supplying the F-containing substance in step B are exemplified as follows:
Processing temperature: room temperature (25 degrees C.) to 200 degrees C., specifically 50 to 175 degrees C., more specifically 100 to 150 degrees C., even more specifically 120 to 150 degrees C.
Processing pressure: 10 to 3,000 Pa, specifically 10 to 2,000 Pa
Processing time: 1 to 120 minutes, specifically 1 to 100 minutes
F-containing substance supply flow rate: 0.5 to 3 slm, specifically 1 to 2 slm
Inert gas supply flow rate (for each gas supply pipe): 0 to 10 slm, specifically 1 to 5 slm

In the present disclosure, the notation of a numerical range such as “25 to 200 degrees C.” means that the lower limit value and the upper limit value are included in the range. Therefore, for example, “25 to 200 degrees C.” means “25 degrees C. or higher and 200 degrees C. or lower”. The same applies to other numerical ranges. In the present disclosure, the processing temperature means the temperature of the wafer 200 or the internal temperature of the process chamber 201, and the processing pressure means the internal pressure of the process chamber 201. Further, the processing time means the time during which a process is continued. Further, the supply flow rate of 0 slm means a case where no substance (gas) is supplied. These apply equally to the following description.

Here, if the processing temperature when supplying the F-containing substance in step B is set to less than the room temperature (25 degrees C.), the etching rate can be increased, but if other processes such as a film forming process is performed at least either before or after the etching process, the time (temperature increase time and/or temperature decrease time) for changing the processing temperature between the etching process and the other processes may become too long, which may reduce productivity.

By setting the above-mentioned processing temperature to the room temperature (25 degrees C.) or higher, it is possible to shorten the time required to change the processing temperature between the etching process and the other processes while maintaining a high etching rate, thereby suppressing the reduction in productivity. By setting the processing temperature to 50 degrees C. or higher, it is possible to further shorten the time required to change the processing temperature between the etching process and the other processes while maintaining a high etching rate, thereby further suppressing the reduction in productivity. By setting the processing temperature to 100 degrees C. or higher, it is possible to significantly shorten the time required to change the processing temperature between the etching process and the other processes while maintaining a high etching rate, thereby significantly improving productivity. By setting the processing temperature to 120 degrees C. or higher, it is possible to further significantly shorten the time required to change the processing temperature between the etching process and the other processes while maintaining a high etching rate, thereby further significantly improving productivity.

Further, if the above-mentioned processing temperature is set to a temperature higher than 200 degrees C., it is possible to significantly shorten the time required to change the processing temperature between the etching process and the other processes, but the etching rate may become too low, which may reduce productivity.

By setting the above-mentioned processing temperature to 200 degrees C. or lower, it is possible to suppress the reduction in the etching rate while maintaining a significant reduction in the time required to change the processing temperature between the etching process and the other processes, thereby suppressing the reduction in productivity. By setting the processing temperature to 175 degrees C. or lower, it is possible to further suppress the reduction in the etching rate while maintaining a significant reduction in the time required to change the processing temperature between the etching process and the other processes, thereby further suppressing the reduction in productivity. By setting the processing temperature to 150 degrees C. or lower, it is possible to substantially suppress the reduction in the etching rate while maintaining a significant reduction in the time required to change the processing temperature between the etching process and the other processes, thereby significantly suppress the reduction in productivity.

From the above, it is desirable that the above-mentioned processing temperature is set to the room temperature (25 degrees C.) to 200 degrees C., specifically 50 degrees C. to 175 degrees C., more specifically 100 degrees C. to 150 degrees C., and even more specifically 120 degrees C. to 150 degrees C.

As the F-containing substance, for example, a substance containing hydrogen (H) such as hydrogen fluoride (HF) can be used. In addition, for example, the F-containing substance may be fluorine (F₂), nitrogen trifluoride (NF₃), chlorine trifluoride (ClF₃), chlorine fluoride (ClF), etc. One or more of these can be used as the F-containing substance.

The inert gas may be nitrogen (N₂) gas or a rare gas such as an argon (Ar) gas, a helium (He) gas, a neon (Ne) gas, or a xenon (Xe) gas. One or more of these may be used as the inert gas. This is the same for each step to be described later.

### Step C

After step B is completed, the output of the heater 207 is adjusted so that the temperature of the wafer 200 becomes a predetermined processing temperature to be described later. Then, a first precursor as a first film-forming agent is supplied to the wafer 200 in the process chamber 201.

Specifically, the valve 243b is opened to allow the first precursor to flow into the gas supply pipe 232b. The flow rate of the first precursor is adjusted by the MFC 241b, and the first precursor is supplied into the process chamber 201 via the nozzle 249b and is exhausted through the exhaust port 231a. In this operation, the first precursor is supplied to the wafer 200 from the side of the wafer 200, so that the wafer 200 is exposed to the first precursor (first precursor supply, exposure). At this time, the valves 243f to 243h may be opened to allow an inert gas to be supplied into the process chamber 201 via each of the nozzles 249a to 249c, respectively.

By supplying the first precursor to the wafer 200 under the process conditions to be described later, it is possible to form a predetermined film on the surface of the wafer 200 from which the second N-containing film and the oxide film have been removed, that is, on the exposed surfaces of the first N-containing film and the base, as shown in FIG. 4F. When a substance to be described later is used as the first precursor, it is possible to form a Si film as the predetermined film on the surface of the wafer 200.

After the predetermined film is formed on the surface of the wafer 200 from which the second N-containing film and the oxide film have been removed, the valve 243b is closed to stop the supply of the first precursor into the process chamber 201. Then, the process chamber 201 is purged according to the same processing procedure as the purging in step B.

The process conditions for supplying the first precursor as the first film-forming agent in step C are exemplified as follows:
Processing temperature: 500 to 650 degrees C., specifically 550 to 600 degrees C.
Processing pressure: 4 to 200 Pa, specifically 1 to 120 Pa
Processing time: 10 to 120 minutes, specifically 20 to 60 minutes
First precursor supply flow rate: 0.1 to 5 slm, specifically 0.2 to 3 slm
Inert gas supply flow rate (for each gas supply pipe): 0 to 10 slm, specifically 0.1 to 5 slm

As the first precursor, for example, silicon hydrides such as monosilane (SiH₄), disilane (Si₂H₆), trisilane (Si₃H₈), and tetrasilane (Si₄H₁₀) can be used.

### (After-Purging and Returning to Atmospheric Pressure)

After step C is completed, an inert gas acting as a purge gas is supplied into the process chamber 201 from each of the nozzles 249a to 249c and is exhausted through the exhaust port 231a. Thus, the interior of the process chamber 201 is purged and a gas, reaction by-products, and the like remaining in the process chamber 201 are removed from the process chamber 201 (after-purging). After that, the internal atmosphere of the process chamber 201 is substituted with an inert gas (inert gas substitution) and the internal pressure of the process chamber 201 is returned to the atmospheric pressure (returning to atmospheric pressure).

### (Boat Unloading)

After that, the seal cap 219 is moved down by the boat elevator 115 to open the lower end of the manifold 209. Then, the processed wafers 200 supported by the boat 217 are unloaded from the lower end of the manifold 209 to the outside of the reaction tube 203 (boat unloading). After the boat unloading, the shutter 219s is moved and the lower end opening of the manifold 209 is sealed by the shutter 219s via the O-ring 220c (shutter close). After that, the processed wafers 200 are discharged from the boat 217 (wafer discharging).

This completes the processing process in embodiments of the present disclosure.

Note that it is preferable that the above-described steps B and C are performed in the same process chamber (in-situ). If a series of processes are performed in-situ, the wafer 200 is not exposed to the atmosphere in the middle, making it possible to perform a consistent and stable process while the wafer 200 is placed under vacuum. In addition, while these embodiments uses the F-containing substance supply system, the first precursor supply system, and the inert gas supply system, it does not use the second precursor supply system, the dopant agent supply system, the modifying agent supply system, the reactant supply system, and the removing agent supply system, so these supply systems can be omitted.

### (3) Effects of the Present Embodiments

According to the present embodiments, one or more effects set forth below may be achieved.
(a) Step A is performed to prepare a substrate including the N-containing film, which is formed with the thickness T₂ thicker than the originally required thickness T₁, and the oxide film on the surface of the substrate, and then step B is performed to supply the F-containing substance to the substrate. This makes it possible to etch the oxide film on the surface of the substrate using the substance X generated by chemically reacting the second N-containing film with the F-containing substance. The action of the substance X promotes the etching reaction of the oxide film, making it possible to perform etching efficiently.

In addition, by using the substance X, it is possible to increase the processing temperature when etching the oxide film. As a result, when performing other processes such as a film forming process at least either before or after the etching process, it is possible to make the processing temperature in the etching close to the processing temperature in the other processes. This makes it possible to shorten the time for changing the processing temperature between the etching process and the other processes, i.e., at least either the temperature rise time or the temperature fall time, and accordingly increases productivity.

Further, by increasing the processing temperature in the etching, it is possible to decompose and remove the solid reaction product generated during the reaction while the F-containing substance is being supplied. This makes it possible to prevent the solid reaction product generated during the reaction from remaining formed on the outermost surface of the oxide film to be etched, that is, remaining in a solid state, thereby preventing the reaction from proceeding any further. This also makes it unnecessary to perform a separate process of sublimating the solid reaction product by increasing the processing temperature after stopping the supply of the F-containing substance, and accordingly increases productivity.

Further, when etching oxide films on the surfaces of a plurality of substrates, the substance X can be generated on the surface of each substrate, making it possible to improve the uniformity between substrates in the process of etching the oxide film.

Further, it is unnecessary to provide a separate supply line for supplying the substance X, making it possible to reduce the apparatus device accordingly. Further, as much as the supply line for supplying the substance X can be omitted, the supply system can be simplified, making it possible to reduce the labor and cost required for maintenance of the supply system. Further, there is no need to place a member (such as a dummy wafer with a N-containing film formed on its surface) for generating the substance X in situ near the substrate, eliminating a need to reduce the number of substrates to be processed at one time. This makes it possible to avoid an increase in processing costs.

Further, the stacked film of the first N-containing film and the second N-containing film is formed in advance on the surface of the substrate prepared in step A. This makes it possible to omit the modifying agent supply system, the removing agent supply system, the reactant supply system, etc., and accordingly simplifies the supply system, making it possible to reduce the labor and cost required for maintenance of the supply system.
(b) The second N-containing film contains Si, and the F-containing substance contains H. This makes it possible to effectively obtain the above-mentioned action. In addition, the second N-containing film includes a SiN film, and the F-containing substance includes HF. This makes it possible to effectively obtain the above-mentioned action.
(c) The substance X contains N and H. In addition, the substance X is generated in the process of etching the second N-containing film by the F-containing substance. In addition, the substance X is generated by decomposition of the reaction product generated in the process of etching the second N-containing film by the F-containing substance. At least one of these makes it possible to effectively obtain the above-mentioned action.
(d) The oxide film includes a SiO film. In addition, the oxide film includes at least one of a non-stoichiometric SiO film and a stoichiometric SiO film. In addition, the oxide film includes at least one of a native oxide film and a chemical oxide film. At least one of these makes it possible to effectively obtain the above-mentioned action.
(e) After step B, step C is performed. This makes it possible to reduce the impurity concentration (oxygen concentration, etc.) at the interface between the substrate and the film formed in step C.
(f) Of the N-containing films, the etching resistance of the first N-containing film by the F-containing substance is higher than the etching resistance of the second N-containing film by the F-containing substance. In addition, the etching resistance of the N-containing film by the F-containing substance at least in the portion of the first N-containing film that contacts the second N-containing film is higher than the etching resistance of the second N-containing film by the F-containing substance. By using at least one of these, it is possible to suppress over-etching of the N-containing film in step B, remove the portion of the N-containing film having the thickness T₂, and leave the portion of the N-containing film having the thickness T₁ with high precision.
(g) The above-described effects can be obtained in the same way even when a predetermined substance is arbitrarily selected from the above-mentioned various F-containing substances, various first film-forming agents (first precursors), and various inert gases.

### (4) Modifications

The processing sequence in the present embodiments can be changed as in the following modifications. These modifications can be used in proper combination. Unless otherwise stated, the processing procedures and process conditions in each step of each modification can be the same as the processing procedures and process conditions in each step of the above-described processing sequence.

### Modification 1

In step A, the second N-containing film with the thickness T₂ may be formed on the first N-containing film with the thickness T₁ formed in advance on the surface of the wafer 200.

In this case, step A includes:
(a1) step A1 of supplying a modifying agent to the wafer 200 to adsorb an inhibitor contained in the modifying agent on the surface of the oxide film; and
(a2) step A2 of supplying a second film-forming agent to the wafer 200 with the inhibitor adsorbed on the surface of an oxide film to form a N-containing film including a stacked film of a first N-containing film with a thickness T₁ and a second N-containing film with a thickness T₂ on the surface of the wafer 200.

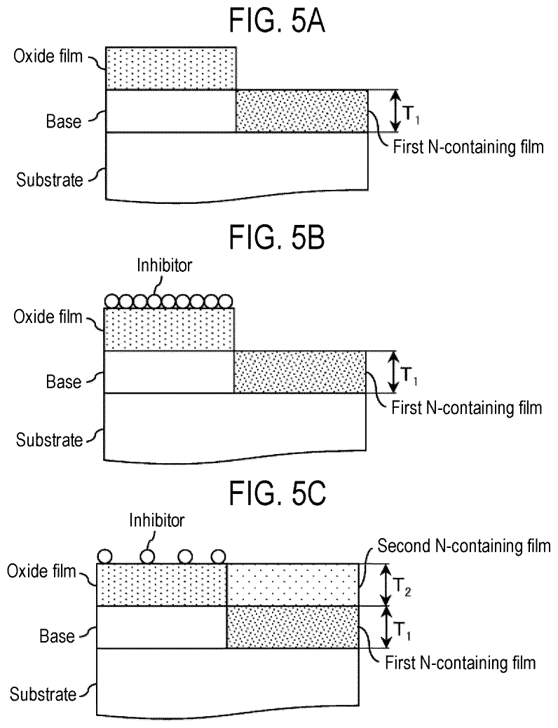

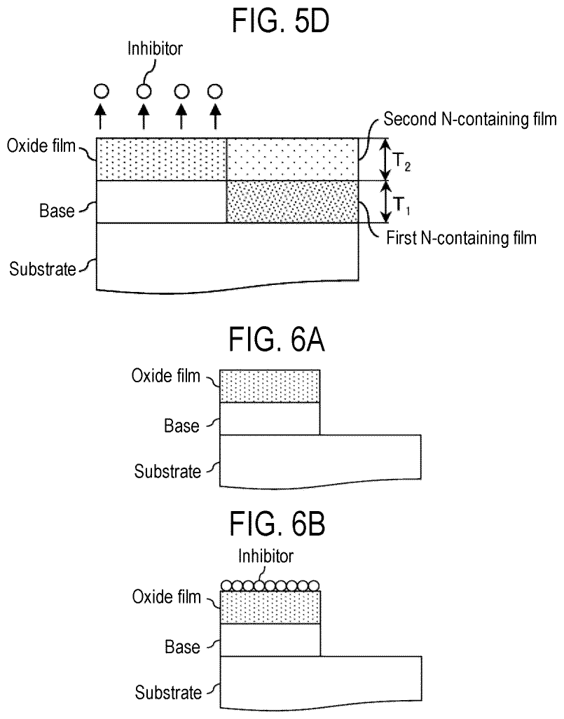

Step A of this modification will be described below mainly with reference to FIGS. 5A to 5D.

First, the wafer 200 to be processed is prepared in the process chamber 201 according to the same processing procedure as the above-described wafer charging to boat loading. As shown in FIG. 5A, the first N-containing film with the thickness T₁ and the oxide film are formed in advance on the surface of the wafer 200 in this modification. A second N-containing film is not formed on the first N-containing film. The surface of the first N-containing film is in an exposed state.

### Step A1

After the temperature adjustment and pressure adjustment in the process chamber 201 are completed, a modifying agent is supplied to the wafer 200 in the process chamber 201.

Specifically, the valve 243d is opened to allow the modifying agent to flow into the gas supply pipe 232d. The flow rate of the modifying agent is adjusted by the MFC 241d, and the modifying agent is supplied into the process chamber 201 via the gas supply pipe 232a and the nozzle 249a and is exhausted through the exhaust port 231a. In this operation, the modifying agent is supplied to the wafer 200 from the side of the wafer 200, so that the wafer 200 is exposed to the modifying agent (modifying agent supply, exposure). At this time, the valves 243f to 243h may be opened to allow an inert gas to be supplied into the process chamber 201 via the nozzles 249a to 249c, respectively.

By supplying the modifying agent to the wafer 200 under the process conditions to be described later, it is possible to adsorb the inhibitor contained in the modifying agent on the surface of the oxide film to selectively form an inhibitor layer on the surface of the oxide film out of the oxide film and the first N-containing film, as shown in FIG. 5B. The inhibitor contains at least a part of the molecular structure of molecules constituting the modifying agent, that is, a residue contained in the modifying agent and derived from the modifying agent. The inhibitor layer is an aggregate of inhibitors, and includes a high-density layer that densely covers the surface of the oxide film. The inhibitor layer functions to suppress or inhibit (block) the progress of the film formation reaction on the oxide film in step A2 to be described later. The above-mentioned effect by the inhibitor layer is also referred to as an inhibitor effect (film formation suppression effect, film formation inhibition effect).

Note that in the present disclosure, for example, an expression such as “selectively forming a layer on a first surface out of the first surface and a second surface” refers to the relative relationship of the degree to which a layer is formed on each surface. In other words, this expression means that a layer is formed so that the degree to which a layer is formed on the first surface is higher than the degree to which a layer is formed on the second surface. In other words, the expression “selectively” in the present disclosure means that a process on one surface is given priority over a process on the other surface. This point is the same in the following explanations.

After the inhibitor layer is formed on the surface of the oxide film, the valve 243d is closed to stop the supply of the modifying agent into the process chamber 201. Then, the process chamber 201 is purged according to the processing procedure as the purging in step B of the above-described embodiments.

The process conditions for supplying the modifying agent in step A1 are exemplified as follows:
Processing temperature: room temperature (25 degrees C.) to 200 degrees C., specifically room temperature to 250 degrees C.
Processing pressure: 1 to 2,000 Pa, specifically 10 to 1,000 Pa
Processing time: 1 to 3,600 seconds, specifically 5 to 300 seconds
Modifying agent supply flow rate: 0.001 to 10 slm, specifically 0.1 to 0.5 slm
Inert gas supply flow rate (for each gas supply pipe): 0 to 20 slm

As the modifying agent, for example, an organic substance containing at least one of a hydrocarbon group and an amino group and/or an inorganic substance containing a halogen can be used. When both substances are used, it is preferable to first supply the organic substance, then perform purging, and then supply the inorganic substance. When the following substances are used, the surface of the oxide film is terminated with a hydrocarbon group such as an alkyl groups, H, Cl, F, etc., and a hydrocarbon group termination such as an alkyl group termination, a H termination, a Cl termination, a F termination, etc. function as an inhibitor.

Examples of the modifying agent may include (dipropylamino)trimethylsilane ((C₃H₇)₂NSi(CH₃)₃), (dibutylamino)trimethylsilane ((C₄H₉)₂NSi(CH₃)₃), (dimethylamino)trimethylsilane ((CH₃)₂NSi(CH₃)₃), (diethylamino)triethylsilane ((C₂H₅)₂NSi(C₂H₅)₃), (dimethylamino)triethylsilane ((CH₃)₂NSi(C₂H₅)₃), (diethylamino)trimethylsilane ((C₂H₅)₂NSi(CH₃)₃), (trimethylsilyl)amine ((CH₃)₃SiNH₂), (triethylsilyl)amine ((C₂H₅)₃SiNH₂), (dimethylamino)silane ((CH₃)₂NSiH₃), (diethylamino)silane ((C₂H₅)₂NSiH₃), (dipropylamino)silane ((C₃H₇)₂NSiH₃), (dibutylamino)silane ((C₄H₉)₂NSiH₃), hydrogen chloride (HCl), chlorine (Cl₂), ClF₃, F₂, etc. One or more of these can be used as the modifying agent.

### Step A2

After step A1 is completed, step A2a is performed to supply a second precursor as a second film-forming agent to the wafer 200 in the process chamber 201, and step A2b is performed to supply a reactant as the second film-forming agent to the wafer 200.

### Step A2a

In this step, the second precursor is supplied to the wafer 200 in the process chamber 201 according to the same processing procedure as in step C of the above-described embodiments.

By supplying the second precursor to the wafer 200 under the process conditions to be described later, it is possible to promote selective adsorption of at least a part of the molecular structure of molecules constituting the second precursor on the surface of the first N-containing film while suppressing adsorption of at least a part of the molecular structure of the molecules constituting the second precursor on the surface of the oxide film. This makes it possible to form a first layer in which at least a part of the molecular structure of the molecules constituting the second precursor is selectively (preferentially) adsorbed on the surface of the first N-containing film.

After the first layer is formed on the surface of the first N-containing film, the supply of the second precursor is stopped. Then, the process chamber 201 is purged according to the same processing procedure as the purging in step B of the above-described embodiments.

Examples of the second precursor may include a substance in which a chloro group (Cl) is bonded to Si, i.e., chlorosilane, such as monochlorosilane (SiH₃Cl), dichlorosilane (SiH₂Cl₂), trichlorosilane (SiHCl₃), tetrachlorosilane (SiCl₄), hexachlorodisilane (Si₂Cl₆), octachlorotrisilane (Si₃Cl₈), etc. In addition, examples of the second precursor may include a substance in which H and an amino group are bonded to Si, i.e., aminosilane, such as tetrakis(dimethylamino)silane (Si[N(CH₃)₂]₄), tris(dimethylamino)silane (Si[N(CH₃)₂]₃H), bis(diethylamino)silane (Si[N(C₂H₅)₂]₂H₂), etc. One or more of these can be used as the second precursor.

The process conditions for supplying the second precursor as the second film-forming agent in step A2a are exemplified as follows:
Processing temperature: room temperature (25 degrees C.) to 700 degrees C., specifically 350 to 550 degrees C.
Processing pressure: 1 to 2,000 Pa, specifically 1 to 1,333 Pa
Processing time: 1 to 180 seconds, specifically 10 to 120 seconds
Second precursor supply flow rate: 0.001 to 2 slm, specifically 0.01 to 1 slm
Inert gas supply flow rate (for each gas supply pipe): 0 to 10 slm, specifically 0.1 to 5 slm

### Step A2b

In this step, the reactant is supplied to the wafer 200 in the process chamber 201.

Specifically, the valve 243e is opened to allow the reactant to flow into the gas supply pipe 232e. The flow rate of the reactant is adjusted by the MFC 241e, and the reactant is supplied into the process chamber 201 via the gas supply pipe 232b and the nozzle 249b and is exhausted through the exhaust port 231a. In this operation, the reactant is supplied to the wafer 200 from the side of the wafer 200, so that the wafer 200 is exposed to the reactant (reactant supply, exposure). At this time, the valves 243f to 243h may be opened to allow an inert gas to be supplied into the process chamber 201 via the nozzles 249a to 249c, respectively.

By supplying the reactant to the wafer 200 under the process conditions to be described later, it is possible to change (nitride) at least a part of the first layer formed on the surface of the first N-containing film in step A2a. As a result, a second layer is formed on the surface of the first N-containing film by selectively (preferentially) nitriding the first layer.

After the second layer is formed on the surface of the first N-containing film, the valve 243e is closed to stop the supply of the reactant into the process chamber 201. Then, the process chamber 201 is purged according to the same processing procedure as the purging in step B of the above-described embodiments.

As the reactant, for example, a nitriding agent (nitriding gas) can be used. Examples of the nitriding agent may include a N- and H-containing substance such as ammonia (NH₃), diazene (N₂H₂), hydrazine (N₂H₄), N₃H₈, etc., i.e., hydrogen nitride. One or more of these can be used as the reactant.

The process conditions for supplying the reactant as the second film-forming agent in step A2b are exemplified as follows:
Processing pressure: 1 to 4,000 Pa, specifically 1 to 1,333 Pa
Reactant supply flow rate: 0.01 to 20 slm, specifically 0.01 to 10 slm
Other process conditions can be the same as those in step A2a.

### [Performing Predetermined Number of Times]

By performing a cycle a predetermined number of times (n times, where n is an integer of 1 or 2 or more), the cycle including the above-described steps A2a and A2b, it is possible to form a second N-containing film with a thickness T₂ on the first N-containing film, as shown in FIG. 5C. The above cycle may be repeated a plurality of times. That is, the thickness of the second layer formed per cycle may be set to be smaller than a desired film thickness, and the above cycle may be repeated a plurality of times until the thickness of a second N-containing film formed by stacking second layers reaches a predetermined thickness T₂.

### Step A3

After step A2 is completed, a removing agent is supplied to the wafer 200 in the process chamber 201 according to the same processing procedure as the above-described step A2b.

By supplying the removing agent to the wafer 200 under the process conditions to be described later, it is possible to at least either remove or disable the inhibitor layer remaining on the surface of the oxide film, as shown in FIG. 5D. FIG. 5D shows a case where the inhibitor layer remaining on the surface of the oxide film is removed.

After that, the supply of the removing agent is stopped. Then, the process chamber 201 is purged according to the same processing procedure as the purging in step B of the above-described embodiments.

The process conditions for supplying the removing agent in step A3 are exemplified as follows:
Processing temperature: 200 to 1,000 degrees C., specifically 400 to 700 degrees C.
Processing pressure: 1 to 120,000 Pa
Processing time: 1 to 18,000 seconds
Removing agent supply flow rate: 0 to 50 slm
RF power: 0 to 10,000 W

Note that RF power is the power applied to generate plasma when performing plasma processing using a removing agent. In addition, a removing agent supply flow rate of 0 slm means a case where no removing agent is supplied. In other words, it is possible to at least either remove or disable the inhibitor layer remaining on the surface of the oxide film without supplying a removing agent, for example, by using thermal energy from heating.

Examples of the removing agent may include an oxygen (O)-containing substance such as oxygen (O₂), ozone (O₃), H₂O, hydrogen peroxide (H₂O₂), hydrogen (H₂)+O₂, H₂+O₃, deuterium (D₂)+O₂, D₂+O₃, nitrous oxide (N₂O), nitric oxide (NO), nitrogen dioxide (NO₂), carbon dioxide (CO₂), carbon monoxide (CO), etc., a N- and H-containing substance such as NH₃, N₂H₂, N₂H₄, etc., a reducing substance such as H₂, D₂, etc., an inert gas such as a He gas, an Ar gas, a N₂ gas, etc., or mixtures of these.

In the present disclosure, the description of two substances such as “H₂+O₂” together means a mixture of H₂ and O₂. When supplying the mixture, the two substances may be mixed (pre-mixed) in a supply pipe and then supplied into the process chamber 201, or the two substances may be supplied separately from different supply pipes into the process chamber 201 and then mixed (post-mixed) in the process chamber 201.

The above completes step A of this modification. After that, steps B and C of the above-described embodiments can be performed.

This modification also provides the same effects as the above-described embodiments. In addition, according to this modification, by performing steps A1 and A2, it is possible to selectively form the second N-containing film with the thickness T₂ on the first N-containing film with the thickness T₁ that has been formed in advance on the surface of the substrate. This makes it possible to efficiently prepare the wafer 200 including the N-containing film formed to be thicker by the thickness T₂ than the originally required thickness T₁, and the oxide film on the surface of the wafer 200.

In addition, according to this modification, after performing steps A1 and A2, step A3 is performed to remove and/or disable the inhibitor layer remaining on the surface of the oxide film. This makes it possible to suppress the etching of the oxide film in step B from being hindered by the inhibitor layer remaining on the surface of the oxide film. As a result, it is possible to smoothly start and efficiently perform the etching of the oxide film in step B.

Note that FIG. 5D shows a case in which the inhibitor layer remaining on the surface of the oxide film is completely removed in step A3, but if the inhibitor effect of the inhibitor layer is sufficiently reduced or disabled after the completion of step A2, it is not always necessary to completely remove the inhibitor layer in step A3. In addition, after the completion of step A2, if no inhibitor layer remains on the surface of the oxide film or if the inhibitor effect of the inhibitor layer remaining on the surface of the oxide film is sufficiently reduced or disabled, it is possible to omit the implementation of step A3.

In other words, in this modification, it is also possible to perform step B in a state in which the inhibitor adsorbed on the surface of the oxide film in step A1 remains. In this case, the inhibitor remaining on the surface of the oxide film is removed together with the oxide film when the oxide film is etched in step B. In this way, by minimizing the amount of inhibitor layer removed or omitting the removal of the inhibitor layer, it is possible to shorten or omit the time required for removing the inhibitor layer, and it is possible to increase the productivity of the substrate processing accordingly.

In addition, in step A2 of this modification, the process conditions can be appropriately selected so that the etching resistance of the second N-containing film by the F-containing substance is lower than the etching resistance of the first N-containing film by the F-containing substance. For example, the processing temperature when the second N-containing film is formed is set to be lower than the processing temperature when the first N-containing film is formed. This allows the second N-containing film to have a lower purity and density than the first N-containing film. In other words, the second N-containing film can be a film with a large amount of impurities and a low density. As a result, it is possible to make the etching resistance of the second N-containing film by the F-containing substance lower than the etching resistance of the first N-containing film by the F-containing substance.

In addition, in step A2 of this modification, the processing procedure in step A2 can be arranged so that the etching resistance by the F-containing substance in at least the portion of the first N-containing film that contacts the second N-containing film is higher than the etching resistance of the second N-containing film by the F-containing substance. For example, before forming the second N-containing film, heat treatment (thermal nitridation treatment, annealing treatment, etc.) or plasma treatment (plasma nitridation treatment, etc.) is performed on the first N-containing film that has been formed in advance. This makes it possible to make at least the surface of the first N-containing film more highly purified, denser (compact), and harder than the second N-containing film. As a result, the etching resistance by the F-containing substance in at least the portion of the first N-containing film that contacts the second N-containing film is made higher than the etching resistance of the second N-containing film by the F-containing substance, so that the surface of the first N-containing film can be given the function of an etching stopper layer. In addition, for example, before forming the second N-containing film, an etching stopper layer having a higher etching resistance than the first N-containing film can be formed on the first N-containing film that has been formed in advance. Note that, when the formation of the etching stopper layer involves heat treatment or plasma treatment, it can be said that this is also a type of heat treatment or plasma treatment for the first N-containing film.

By using at least one of these methods, it is possible to suppress over-etching of the N-containing film in step B, remove the portion of the N-containing film with the thickness T₂, and leave the portion of the N-containing film with the thickness T₁ with high precision.

The process conditions for the heat treatment or plasma treatment of the first N-containing film in step A2 are exemplified as follows:
Processing temperature: room temperature (25 degrees C.) to 800 degrees C., specifically 300 to 700 degrees C.
Processing pressure: 1 to 5,000 Pa, specifically 1 to 3,000 Pa
Processing time: 1 to 300 seconds, specifically 1 to 200 seconds
Reactant supply flow rate: 0 to 20 slm, specifically 0.01 to 10 slm
Inert gas supply flow rate: 0 to 20 slm
RF power: 0 to 10,000 W

As the reactant, the same substances as the various nitriding agents exemplified above can be used.

### Modification 2

In step A, a stacked film of the first N-containing film with the thickness T₁ and the second N-containing film with the thickness T₂ may be formed on the surface of the wafer 200 on which no N-containing film is formed. In this case, step A can include step A1 of supplying a modifying agent to the wafer 200 and step A2 of supplying a second film-forming agent to the wafer 200, as in Modification 1.

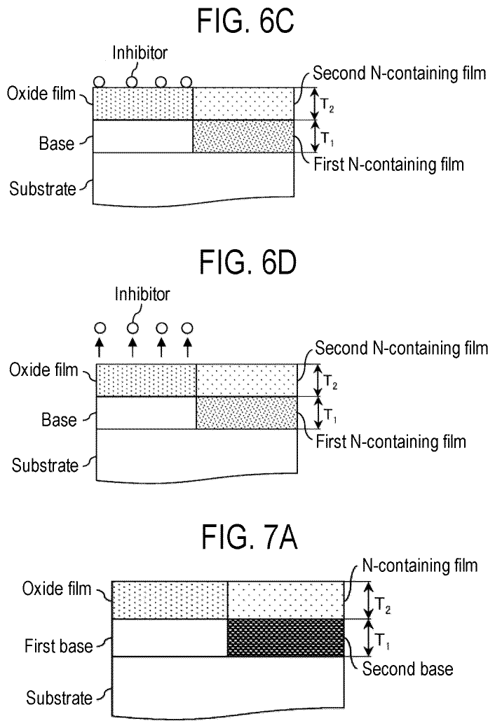

Step A of this modification will be described below mainly with reference to FIGS. 6A to 6D.

First, the wafer 200 to be processed is prepared in the process chamber 201 according to the same processing procedure as the above-described wafer charging to boat loading. As shown in FIG. 6A, the oxide film is formed in advance on the surface of the wafer 200 in this modification, and neither the first nor the second N-containing film is formed thereon. The surface of the wafer 200 is partially exposed, and this partially exposed surface of the wafer 200 will hereinafter be referred to as an exposed surface of the wafer 200.

### Step A1

After the temperature adjustment and pressure adjustment in the process chamber 201 are completed, a modifying agent is supplied to the wafer 200 in the process chamber 201 under the same processing procedure and process conditions as those in step A1 of the first modification. As a result, as shown in FIG. 6B, it is possible to adsorb an inhibitor contained in the modifying agent on the surface of the oxide film out of the surface of the oxide film and the exposed surface of the wafer 200 to selectively form an inhibitor layer.

After the inhibitor layer is formed on the surface of the oxide film, the supply of the modifying agent is stopped. Then, the process chamber 201 is purged according to the same processing procedure as the purging in step B of the above-described embodiments.

### Step A2

After step A1 is completed, a stacked film of the first N-containing film with the thickness T₁ and the second N-containing film with the thickness T₂ is formed on the exposed surface of the wafer 200, as shown in FIG. 6C.

The first and second N-containing films can be formed according to the same processing procedure and process conditions as step A2 of Modification 1. That is, by performing a cycle a predetermined number of times (n₁ times, where n₁ is an integer of 1 or 2 or more), the cycle including steps A2a and A2b of Modification 1, the first N-containing film with the thickness T₁ can be formed on the exposed surface of the wafer 200. After that, by performing this cycle a predetermined number of times (n₂ times, where n₂ is an integer of 1 or 2 or more), the second N-containing film with the thickness T₂ can be formed on the first N-containing film. As in Modification 1, each of these cycles may be repeated a plurality of times.

### Step A3

After step A2 is completed, a removing agent is supplied to the wafer 200 in the process chamber 201 according to the same processing procedure as step A3 of Modification 1. As a result, as shown in FIG. 6D, it is possible to at least either remove or disable the inhibitor layer remaining on the surface of the oxide film. FIG. 6D shows a case where the inhibitor layer remaining on the surface of the oxide film is removed.

This completes step A of this modification. After that, steps B and C of the above-described embodiments can be performed.

This modification also provides the same effects as the above-described embodiments and Modification 1. In addition, according to this modification, by performing steps A1 and A2, it is possible to selectively form the N-containing film including the stacked film of the first N-containing film with the thickness T₁ and the second N-containing film with the thickness T₂ on the exposed surface of the substrate. This makes it possible to selectively form (prepare) the N-containing film, which is formed to be thicker by the thickness T₂ than the originally required thickness T₁, at a desired location on the surface of the substrate.

In addition, according to this modification, step A3 is performed after steps A1 and A2 are performed, as in Modification 1. As a result, it is possible to smoothly start and efficiently perform the etching of the oxide film in step B.

Note that as in Modification 1, after the completion of step A2, depending on the situation, the amount of the inhibitor layer removed in step A3 can be minimized, or the implementation of step A3 can be omitted. That is, it is also possible to perform step B in a state in which the inhibitor adsorbed on the surface of the oxide film in step A1 remains. In this case, it is possible to increase the productivity of the substrate processing.

In addition, in step A2 of this modification, the process conditions can be appropriately selected so that the etching resistance of the first N-containing film by the F-containing substance is higher than the etching resistance of the second N-containing film by the F-containing substance. For example, the processing temperature when forming the first N-containing film is set to be higher than the processing temperature when forming the second N-containing film. Specifically, for example, the processing temperature when forming the first N-containing film is set to 630 degrees C. or higher and 700 degrees C. or lower, and the processing temperature when forming the second N-containing film is set to 500 degrees C. or higher and lower than 630 degrees C. This makes it possible to make the first N-containing film more highly purified, denser (compact), and harder than the second N-containing film. That is, the first N-containing film can be a film with fewer impurities, higher density (compactness), and higher hardness. As a result, it is possible to make the etching resistance of the first N-containing film by the F-containing substance higher than the etching resistance of the second N-containing film by the F-containing substance.

In addition, in step A2 of this modification, the processing procedure in step A2 can be arranged so that the etching resistance by the F-containing substance in at least the portion of the first N-containing film that contacts the second N-containing film is higher than the etching resistance of the second N-containing film by the F-containing substance. For example, after forming the first N-containing film and before forming the second N-containing film, heat treatment (thermal nitridation treatment, annealing treatment, etc.) or plasma treatment (plasma nitridation treatment, etc.) is performed on the first N-containing film under the same process conditions as those shown in Modification 1. This makes it possible to make at least the surface of the first N-containing film more highly purified, denser (compact), and harder than the second N-containing film. As a result, the etching resistance by the F-containing substance in at least the portion of the first N-containing film that contacts the second N-containing film is made higher than the etching resistance of the second N-containing film by the F-containing substance, so that the surface of the first N-containing film can be given the function of an etching stopper layer. In addition, for example, before forming the second N-containing film, an etching stopper layer having a higher etching resistance than the first N-containing film can be formed on the first N-containing film. Note that, when the formation of the etching stopper layer involves heat treatment or plasma treatment, it can be said that this is also a type of heat treatment or plasma treatment for the first N-containing film.

By using at least one of these methods, it is possible to suppress over-etching of the N-containing film in step B, remove the portion of the N-containing film with the thickness T₂, and leave the portion of the N-containing film with the thickness T₁ with high precision.

### Modification 3

In step B, the supply conditions of the F-containing substance, i.e., the process conditions when the F-containing substance is supplied to the wafer 200, may be changed in multiple stages, for example, in two stages.

For example, in step B, the supply flow rate of the F-containing substance to the wafer 200, the supply flow rate of the inert gas, the concentration (partial pressure) of the F-containing substance, the dilution rate of the F-containing substance, etc. may be changed in multiple stages. For example, in the latter half or final stage of step B, the supply flow rate of the F-containing substance may be set to be lower than the previous supply flow rate of the F-containing substance. In addition, for example, in the latter half or final stage of step B, the supply flow rate of the inert gas may be set to be higher than the previous supply flow rate of the inert gas. In addition, for example, in the latter half or final stage of step B, the dilution rate of the F-containing substance may be set to be higher than the previous dilution rate of the F-containing substance, and the concentration (partial pressure) of the F-containing substance may be set to be lower than the previous concentration (partial pressure) of the F-containing substance.

For example, in a state where the supply flow rate of the inert gas in step B is set to a predetermined flow rate of 0.5 slm or more and 10 slm or less, the supply flow rate of the F-containing substance in the latter half or final stage of step B is set to be lower than the previous supply flow rate of the F-containing substance, thereby realizing any one of these. In addition, in a state where the supply flow rate of the F-containing substance in step B is set to a predetermined flow rate of 0.5 slm or more and 3 slm or less, the supply flow rate of the inert gas in the latter half or final stage of step B is set to be higher than the previous supply flow rate of the inert gas, thereby realizing any one of these. In addition, the supply flow rate of the F-containing substance in the latter half or final stage of step B is set to be lower than the previous supply flow rate of the F-containing substance, and the supply flow rate of the inert gas in the latter half or final stage of step B is set to be higher than the previous supply flow rate of the inert gas up, thereby realizing any one of these.

This modification also provides the same effects as the above-described embodiments. In addition, according to this modification, in the latter half or final stage of step B, the reactivity between the F-containing substance and the N-containing film can be reduced to be lower than the previous reactivity, and the etching rate can be reduced to be lower than the previous etching rate. That is, according to this modification, in step B, the reactivity between the F-containing substance and the N-containing film can be reduced in multiple stages, and the etching rate can be reduced in multiple stages. This makes it possible to suppress over-etching of the N-containing film, remove the portion of the N-containing film with the thickness T₂, and leave the portion of the N-containing film with the thickness T₁ with high precision. In this case, by setting the etching resistance of the first N-containing film by the F-containing substance to be higher than the etching resistance of the second N-containing film by the F-containing substance, or by setting the etching resistance by the F-containing substance at least in the portion of the first N-containing film that contacts the second N-containing film to be higher than the etching resistance of the second N-containing film by the F-containing substance, it is possible to remove the portion of the N-containing film with the thickness T₂ and leave the portion of the N-containing film with the thickness T₁ with high precision.

### Other Embodiments of the Present Disclosure

The embodiments of the present disclosure have been specifically described above. However, the present disclosure is not limited to the above-described embodiments, and various changes can be made without departing from the gist thereof.

For example, in step B of the above-described embodiments, the F-containing gas may be supplied intermittently, i.e., in a pulsed manner, into the process chamber. For example, the supply of the F-containing gas into the process chamber and the purging and/or vacuum-exhaust of the process chamber may be alternately performed a predetermined number of times (m times, where m is an integer of 1 or 2 or more). In this case, the same effects as in the above-described embodiments can be obtained. Further, according to these embodiments, by temporarily removing reaction products and residual gases from the process chamber during etching to reset the reaction, it is possible to suppress the occurrence of an excessive etching reaction, making it possible to improve the controllability of the etching amount.

Further, for example, in step C of the above-described embodiments, the first precursor may be supplied intermittently, i.e., in a pulsed manner, into the process chamber. For example, the supply of the first precursor into the process chamber and the purging and/or vacuum-exhaust of the process chamber may be alternately performed a predetermined number of times (p times, where p is an integer of 1 or 2 or more). In this case, the same effects as in the above-described embodiments can be obtained.

Further, for example, in step C of the above-described embodiments, the dopant agent may be supplied as the first film-forming agent to the substrate in addition to the first precursor. The dopant agent can be supplied from the above-described dopant agent supply system. As the dopant agent, a substance containing any of Group XV elements such as phosphorus (P) and arsenic (As) and Group XIII elements such as boron (B) can be used. As the dopant agent, for example, phosphine (PH₃), arsine (AsH₃), diborane (B₂H₆), trichloroborane (BCl₃), etc. can be used. One or more of these can be used as the dopant agent. In these embodiments, the same effects as in the above-described embodiments can be obtained. According to these embodiments, it is possible to form a film doped with a dopant (P, As, B, etc.) on the substrate.

Further, for example, in step C of the above-described embodiments, a semiconductor element-containing substance other than Si may be used as the first precursor to form a semiconductor element-containing film other than a Si-containing film on the substrate. For example, a Ge-containing substance such as monogermane (GeH₄) may be used as the first precursor to form a Ge-containing film such as a Ge film on the substrate. Further, for example, a Si-containing substance and a Ge-containing substance may be used as the first precursor to form a Si- and Ge-containing film such as a SiGe film on the substrate. Further, for example, a nitriding agent or an oxidizing agent may be used in addition to the semiconductor element-containing substance as the first precursor to form a semiconductor element- and N-containing film such as a SiN film, a SiCN film, a SiON film, a SiOCN film, a SiBCN film, or a SiBN film, or a semiconductor element- and O-containing film such as a SiO film, or a SiOC film on the substrate. Further, a metal element-containing substance may be used as the first precursor to form a metal element-containing film such as a W film, a Mo film, or a Ru film on the substrate. Further, for example, a nitriding agent or an oxidizing agent may be used in addition to the metal element-containing substance as the first precursor to form a metal element- and N-containing film such as a TiN film, a WN film, or an AlN film, or a metal element- and O-containing film such as a TiO film, a HfO film, a ZrO film, or an AlO film. In these cases, the same effects as in the above-described embodiments can be obtained.

Further, for example, in step C of the above-described embodiments, an epitaxial film, a non-crystalline film (amorphous film), a polycrystalline film (poly film), or a mixed crystal film of these may be formed on the substrate. For example, an epitaxial Si film, an amorphous Si film, a poly Si film, or a mixed crystal Si film of amorphous and poly may be formed on the substrate. In these cases, the same effects as in the above-described embodiments can be obtained.

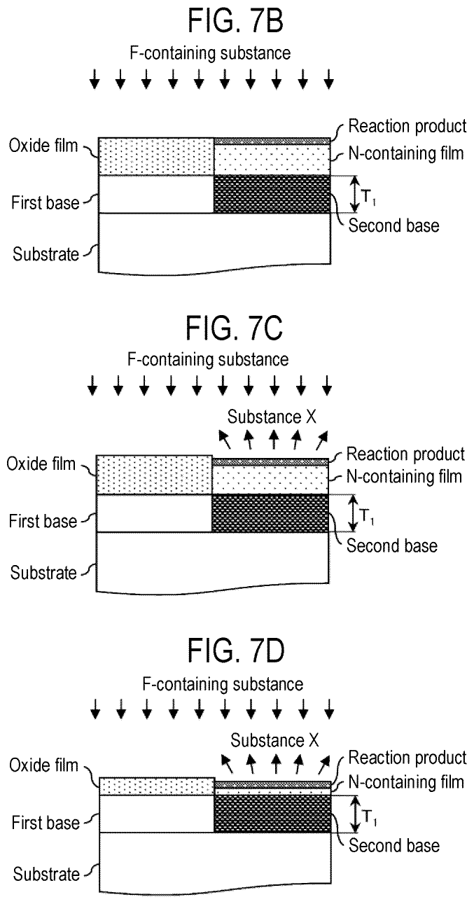

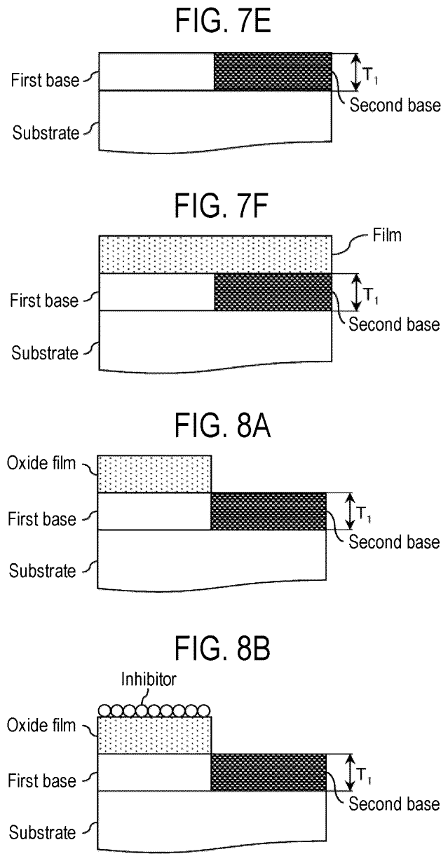

Further, for example, as shown in FIGS. 7A to 7F, the present disclosure may include:
(a) step A of preparing a substrate including a first base and a second base on the surface of the substrate, with an oxide film formed on the surface of the first base and a N-containing film formed on the surface of the second base; and
(b) step B of etching the oxide film on the surface of the substrate using a substance X generated by supplying a F-containing substance to the substrate and chemically reacting the N-containing film with the F-containing substance.

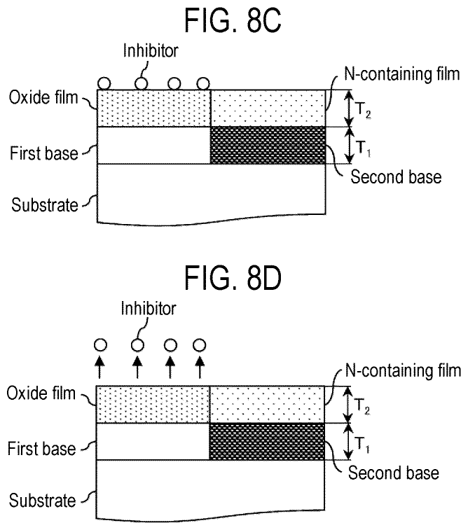

Further, in this case, as shown in FIGS. 8A to 8D, step A may include:
(a1) step A1 of supplying a modifying agent to the substrate to adsorb an inhibitor contained in the modifying agent on the surface of the oxide film; and
(a2) step A2 of supplying a second film-forming agent to the substrate with the inhibitor adsorbed on the surface of the oxide film to form a N-containing film on the surface of the second base,

The embodiments shown in FIGS. 7A to 7F and FIGS. 8A to 8D are partial modifications of the embodiments shown in FIGS. 4A to 4F and FIGS. 5A to 5D. Specifically, FIGS. 7A to 7F and FIGS. 8A to 8D are modifications of FIGS. 4A to 4F and FIGS. 5A to 5D with the change of the “base” to the “first base”, the “first N-containing substance” to the “second base”, and the “second N-containing film” to the “N-containing film”. Here, the “second base” is composed of a non-N-containing substance (non-nitride), such as a semiconductor element-containing film such as a Si film, a Ge film, a SiGe film, a SiOC film, or a SiC film, or a metal element-containing film such as a W film, a Mo film, a Ru film, a HfO film, a ZrO film, or an AlO film. The rest of the configuration is the same as that of each of the embodiments shown in FIGS. 4A to 4F and FIGS. 5A to 5D.

The embodiments shown in FIGS. 7A to 7F and FIGS. 8A to 8D also provide the same effects as those of the above-described embodiments. That is, in step A, instead of preparing a substrate including an oxide film formed on the surface of the base and a second N-containing film formed on the surface of the first N-containing film, a substrate including an oxide film formed on the surface of the first base and a N-containing film formed on the surface of the second base can be prepared to provide the same effects as that of the above-described embodiments.

Further, for example, in step C of the above-described embodiments, a predetermined film may be selectively formed on any part of the plurality of types of surfaces exposed by performing step B. For example, in FIG. 4F, a film may be selectively formed on the surface of the base, or a film may be selectively formed on the surface of the first N-containing film, out of the base and the first N-containing film. Further, for example, in FIG. 7F, a film may be selectively formed on the surface of the first base, or a film may be selectively formed on the surface of the second base. In these cases, the same effects as the above-described embodiments can be obtained.

Recipes used in each process may be prepared individually according to the processing contents and may be recorded and stored in the memory 121c via a telecommunication line or the external memory 123. Moreover, at the beginning of each process, the CPU 121a may properly select an appropriate recipe from the recipes recorded and stored in the memory 121c according to the processing contents. Thus, it is possible for the processing apparatus to perform various processes with enhanced reproducibility. Further, it is possible to reduce an operator's burden and to quickly start each process while avoiding an operation error.

The recipes mentioned above are not limited to newly-prepared ones but may be prepared, for example, by modifying existing recipes that are already installed in the processing apparatus. Once the recipes are modified, the modified recipes may be installed in the processing apparatus via a telecommunication line or a recording medium storing the recipes. In addition, the existing recipes already installed in the existing processing apparatus may be directly modified by operating the input/output device 122 of the processing apparatus.

An example in which a process is performed using a batch-type processing apparatus capable of processing a plurality of substrates at a time has been described in the above-described embodiments. The present disclosure is not limited to the above-described embodiments, but may be applied, for example, to a case where a process is performed using a single-wafer type processing apparatus capable of processing a single substrate or several substrates at a time. In addition, an example in which a process is performed using a processing apparatus provided with a hot-wall-type process furnace has been described in the above-described embodiments. The present disclosure is not limited to the above-described embodiments, but may be applied to a case where a process is performed using a processing apparatus provided with a cold-wall-type process furnace.

In addition, an example in which the above-described processing sequence is performed in the same process chamber of the same processing apparatus (in-situ) has been described the above-described embodiments. The present disclosure is not limited to the above-described embodiments. For example, any step and any other step of the above-described processing sequence may be performed in different process chambers of different processing apparatuses (ex-situ), or may be performed in different process chambers of the same processing apparatus.

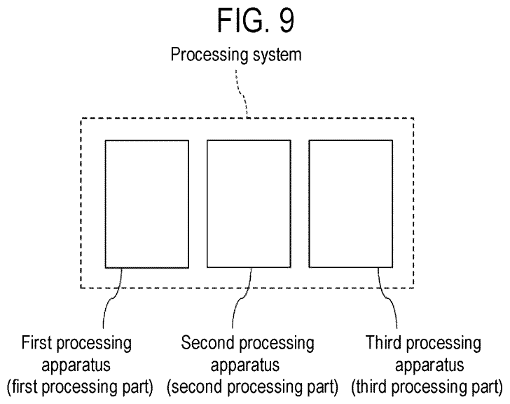

The present disclosure may also be applied to a case where, for example, as shown in FIG. 9, a processing system including a plurality of stand-alone s processing apparatuses (first to third processing apparatuses) is used to perform each step ex-situ in different process chambers of respective different processing apparatuses. For example, step A can be performed in the first processing apparatus, step B can be performed in the second processing apparatus, and step C can be performed in the third processing apparatus. In addition, for example, step A can be performed in the first processing apparatus, and steps B and C can be performed in the second processing apparatus. In addition, for example, steps A and B can be performed in the first processing apparatus, and step C can be performed in the second processing apparatus. In this case, the first to third processing apparatuses are also referred to as first to third processing part, respectively. The processing system is also referred to as a processing apparatus.

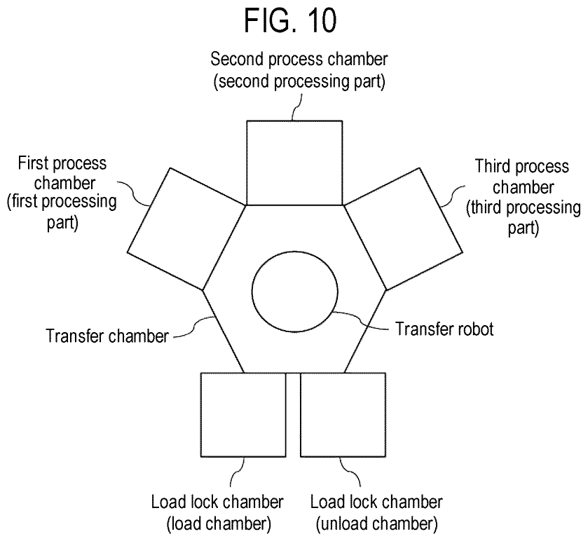

In addition, the present disclosure may also be applied to a case where, for example, as shown in FIG. 10, a processing system including a cluster-type processing apparatus provided with a plurality of process chambers (first to third process chambers) around a transfer chamber is used to perform each step in different process chambers of the same processing apparatus. For example, step A can be performed in the first process chamber, step B can be performed in the second process chamber, and step can be performed in the third process chamber. In addition, for example, step A can be performed in the first process chamber, and steps B and C can be performed in the second process chamber. In addition, for example, steps A and B can be performed in the first process chamber, and step C can be performed in the second process chamber. In this case, the first to third process chambers are also referred to as first to third processing part, respectively. The above-described embodiments and modifications can also be said to be examples in which the first to third processing parts are the same processing part. The processing system is also referred to as a processing apparatus.

Even in the case of using these processing apparatuses (processing systems), each process may be performed according to the same processing procedures and process conditions as those in the above-described embodiments and modifications, and the same effects as the above-described embodiments and modifications can be obtained. In addition, when steps B and C of the above-described processing sequence are performed ex-situ, it is possible to prevent a film-forming agent from introducing into the process chamber where the etching process is performed, and also possible to prevent a F-containing substance from introducing into the process chamber where the film forming process is performed. Therefore, it is possible to prevent cross-contamination in each process chamber, making it possible to improve the quality of each of the etching process and the film forming process.

The above-described embodiments and modifications may be used in proper combination. The processing procedures and process conditions used in this case may be the same as, for example, the processing procedures and process conditions in the above-described embodiments and modifications.

According to the present disclosure in some embodiments, it is possible to efficiently etch an oxide film on the surface of a substrate.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A processing method comprising:
(a) preparing a substrate including a nitrogen-containing film, which is formed to be thicker by a thickness T₂ than a target thickness T₁, and an oxide film on a surface of the substrate; and
(b) etching the oxide film on the surface of the substrate using a substance X generated by supplying a fluorine-containing substance to the substrate and chemically reacting the nitrogen-containing film with the fluorine-containing substance.

2. The processing method of claim 1, wherein the nitrogen-containing film contains silicon, and the fluorine-containing substance contains hydrogen.

3. The processing method of claim 1, wherein the nitrogen-containing film includes a silicon nitride film, and the fluorine-containing substance includes hydrogen fluoride.

4. The processing method of claim 3, wherein the substance X contains nitrogen and hydrogen.

5. The processing method of claim 1, wherein the substance X is generated in a process of etching a portion of the nitrogen-containing film with the thickness T₂ by the fluorine-containing substance.

6. The processing method of claim 1, wherein the substance X is generated by decomposition of a reaction product produced in a process of etching a portion of the nitrogen-containing film with the thickness T₂ by the fluorine-containing substance.

7. The processing method of claim 1, wherein the oxide film includes a silicon oxide film.

8. The processing method of claim 1, wherein the oxide film includes at least one selected from the group of a native oxide film and a chemical oxide film.

9. The processing method of claim 1, further comprising:
(c) supplying a first film-forming agent to the substrate to form a film on the surface of the substrate from which the oxide film is etched.

10. The processing method of claim 1, wherein (a) includes:
(a1) supplying a modifying agent to the substrate to adsorb an inhibitor contained in the modifying agent on the surface of the oxide film; and
(a2) supplying a second film-forming agent to the substrate with the inhibitor adsorbed on the surface of the oxide film to form the nitrogen-containing film including a stacked film of a first nitrogen-containing film with the thickness T₁ and a second nitrogen-containing film with the thickness T₂ on the surface of the substrate.

11. The processing method of claim 10, wherein in (a2), the second nitrogen-containing film is formed on the first nitrogen-containing film that has been previously formed on the surface of the substrate.

12. The processing method of claim 10, wherein in (a2), the stacked film is formed on the surface of the substrate.

13. The processing method of claim 10, wherein (b) is performed in a state where the inhibitor adsorbed on the surface of the oxide film in (a1) remains.

14. The processing method of claim 10, wherein in (a), the nitrogen-containing film is prepared so that an etching resistance of the first nitrogen-containing film by the fluorine-containing substance is higher than an etching resistance of the second nitrogen-containing film by the fluorine-containing substance.

15. The processing method of claim 10, wherein in (a), the nitrogen-containing film is prepared so that an etching resistance by the fluorine-containing substance in at least a portion of the first nitrogen-containing film in contact with the second nitrogen-containing film is higher than an etching resistance of the second nitrogen-containing film by the fluorine-containing substance.

16. The processing method of claim 10, wherein (a) includes at least one selected from the group of:
setting a processing temperature when forming the first nitrogen-containing film to be higher than a processing temperature when forming the second nitrogen-containing film; and
performing heat treatment or plasma treatment on the first nitrogen-containing film after forming the first nitrogen-containing film and before forming the second nitrogen-containing film.

17. The processing method of claim 1, wherein an etching resistance by the fluorine-containing substance in a portion of the thickness T₁ of the nitrogen-containing film is higher than an etching resistance by the fluorine-containing substance in a portion of the thickness T₂ of the nitrogen-containing film.

18. The processing method of claim 1, wherein an etching resistance by the fluorine-containing substance in at least a portion of the thickness T₁ of the nitrogen-containing film in contact with a portion of the thickness T₂ of the nitrogen-containing film is higher than an etching resistance by the fluorine-containing substance in the portion of the thickness T₂ of the nitrogen-containing film.

19. The processing method of claim 1, wherein in (b), supply conditions of the fluorine-containing substance are changed in multiple stages.

20. The processing method of claim 5, wherein in (b), the portion of the nitrogen-containing film with the thickness T₂ is removed and a portion of the nitrogen-containing film with the thickness T₁ is left.

21. A method of manufacturing a semiconductor device, comprising the processing method of claim 1.

22. A processing apparatus comprising:
a device configured to prepare a substrate;
a fluorine-containing substance supply system that supplies a fluorine-containing substance to the substrate; and
a controller configured to be capable of controlling the device and the fluorine-containing substance supply system to perform a process including:
(a) preparing the substrate including a nitrogen-containing film, which is formed to be thicker by a thickness T₂ than a target thickness T₁, and an oxide film on a surface of the substrate; and
(b) etching the oxide film on the surface of the substrate using a substance X generated by supplying the fluorine-containing substance to the substrate and chemically reacting the nitrogen-containing film with the fluorine-containing substance.

23. A non-transitory computer-readable recording medium storing a program that causes, by a computer, a processing apparatus to perform a process comprising:
(a) preparing a substrate including a nitrogen-containing film, which is formed to be thicker by a thickness T₂ than a target thickness T₁, and an oxide film on a surface of the substrate; and
(b) etching the oxide film on the surface of the substrate using a substance X generated by supplying a fluorine-containing substance to the substrate and chemically reacting the nitrogen-containing film with the fluorine-containing substance.
